(19) United States
(12) Patent Application Publication
(10) Pub. No.: US 2025/0359286 A1
(43) Pub. Date: Nov. 20, 2025

(54) Source/Drains for Stacked Device Structures and Methods of Fabrication Thereof

(71) Applicant: Taiwan Semiconductor Manufacturing Company, Ltd., Hsin-Chu (TW)

(72) Inventors: Che Chi SHIH, Taoyuan City (TW); Zhi-Chang LIN, Hsinchu County (TW); Tsung-Kai CHIU, Hsinchu County (TW); Ku-Feng YANG, Hsinchu County (TW); Szuya LIAO, Hsinchu (TW)

(21) Appl. No.: 19/283,563

(22) Filed: Jul. 29, 2025

Related U.S. Application Data
(63) Continuation of application No. 18/592,029, filed on Feb. 29, 2024.
(60) Provisional application No. 63/600,262, filed on Nov. 17, 2023.

(51) Int. Cl. H10D 84/01; H10D 30/43; H10D 30/67; H10D 62/10; H10D 62/13; H10D 84/03; H10D 84/85

(52) U.S. Cl. CPC H10D 84/017; H10D 30/43; H10D 30/6729; H10D 30/6735; H10D 30/6757; H10D 62/121; H10D 62/151; H10D 84/0186; H10D 84/0188; H10D 84/038; H10D 84/856

(57) ABSTRACT

Source/drain fabrication methods for stacked device structures are disclosed herein. An exemplary method for forming a source/drain stack may include a frontside process and a backside process. The frontside process may include forming a frontside source/drain trench, forming a dummy source/drain in the frontside source/drain trench, and forming an upper source/drain in the frontside source/drain trench over the dummy source/drain. The backside process may include exposing a backside of the dummy source/drain, removing (partially or completely) the dummy source/drain to form a backside source/drain trench, and forming a lower source/drain in the backside source/drain trench. The dummy source/drain may be formed of semiconductor material or dielectric material, and a portion of the dummy source/drain may remain between the upper source/drain and the lower source/drain. In some embodiments, the backside process includes replacing substrate/mesa with a backside insulation structure and selectively removing the dummy source/drain relative to the backside insulation structure.

This is a continuation application of U.S. patent application Ser. No. 18/592,029, filed Feb. 29, 2024, which is a non-provisional application of and claims benefit of U.S. Provisional Patent Application Ser. No. 63/600,262, filed Nov. 17, 2023, the entire disclosures of which are incorporated herein by reference.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that may be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, as stacked device structures are introduced to enable further density reduction for advanced IC technology nodes, increasing aspect ratios (e.g., depths/heights to widths) have presented challenges when fabricating stacked source/drains. Although existing stacked source/drain fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A and FIG. 1B are cross-sectional views of a stacked device structure, in portion or entirety, according to various aspects of the present disclosure.

FIG. 2 is a flow chart of a method, in portion or entirety, for fabricating source/drains of a stacked device structure, such as the stacked device structure of FIG. 1A and FIG. 1B, according to various aspects of the present disclosure.

FIGS. 3A-15A and FIGS. 3B-15B are cross-sectional views of a stacked device structure, in portion or entirety, at various fabrication stages associated with the method of FIG. 2 according to various aspects of the present disclosure.

FIGS. 16A-28A and FIGS. 16B-28B are cross-sectional views of another stacked device structure, in portion or entirety, at various fabrication stages associated with the method of FIG. 2 according to various aspects of the present disclosure.

FIGS. 29A-40A and FIGS. 29B-40B are cross-sectional views of yet another stacked device structure, in portion or entirety, at various fabrication stages associated with the method of FIG. 2 according to various aspects of the present disclosure.

### DETAILED DESCRIPTION

The present disclosure generally relates to source/drains for stacked device structures, such as a transistor stack having an n-type field effect transistor (NFET) and a p-type field effect transistor (PFET) (e.g., a complementary field effect transistor (CFET)).

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” may encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Stacked transistor structures provide further density reduction for advanced integrated circuit (IC) technology nodes, especially when the stacked transistor structures include multigate devices, such as fin-like field effect transistors (FinFETs), gate-all-around (GAA) transistors including nanowires and/or nanosheets, other types of multigate devices, etc. Stacked transistor structures vertically stack transistors. For example, a transistor stack may include a first transistor (e.g., a top transistor) disposed over a second transistor (e.g., a bottom transistor). The transistor stack may provide a CFET when the first transistor and the second transistor are of opposite conductivity type (i.e., an n-type transistor and a p-type transistor).

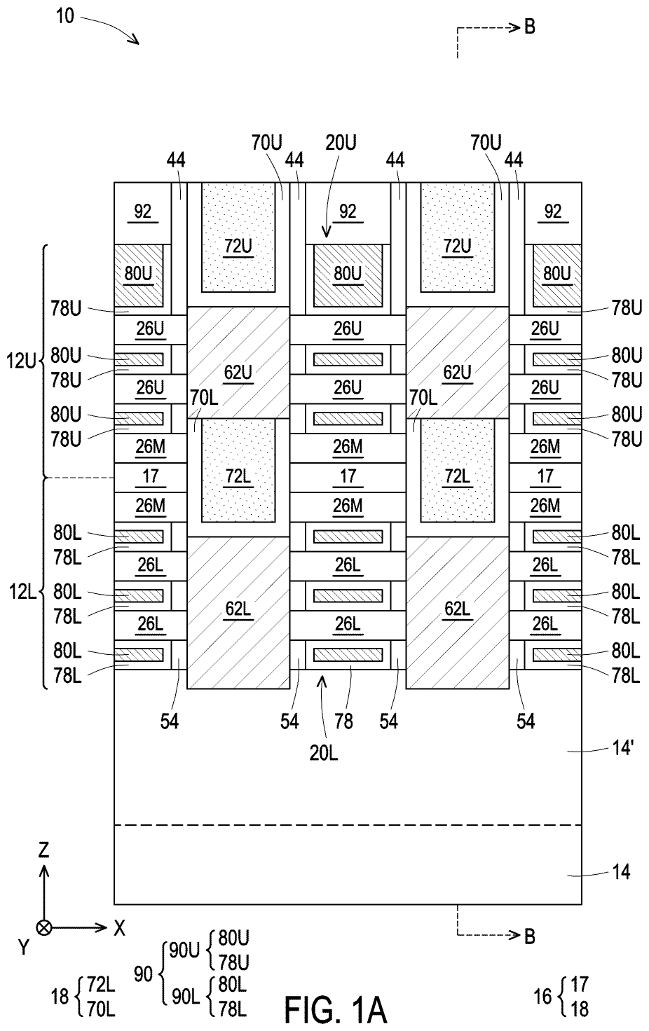

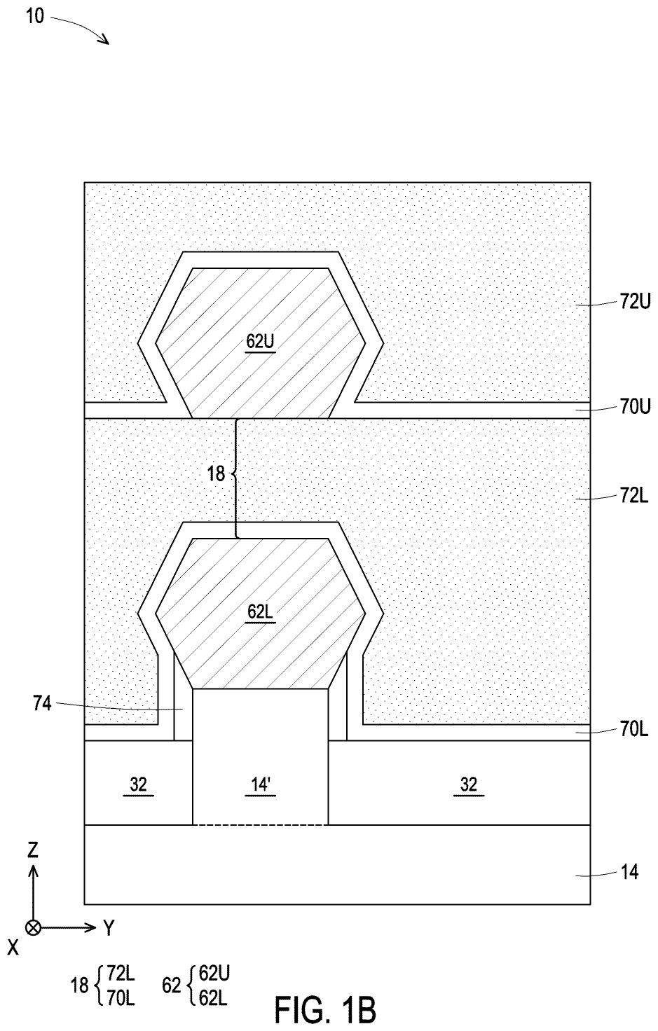

FIG. 1A is a fragmentary cross-sectional view of a stacked device structure 10, in portion or entirety, according to various aspects of the present disclosure. FIG. 1B is a fragmentary cross-sectional view of stacked device structure 10, in portion or entirety, along line B-B of FIG. 1A according to various aspects of the present disclosure. Stacked device structure 10 includes a device stack, such as an upper device 12U vertically stacked over a lower device 12L, disposed over a substrate 14. In the depicted embodiment, device 12U and device 12L are stacked back-to-front. For example, a backside of device 12U is attached and/or bonded to a frontside of device 12L. An insulation structure 16 is disposed between and separates device 12U and device 12L. Insulation structure 16 may be a single layer/feature or a multilayer/feature structure. For example, insulation structure 16 includes an insulation structure 17 and an insulation structure 18. FIG. 1A and FIG. 1B are simplified for the sake of clarity to better understand the inventive concepts of the present disclosure. Additional features may be added in stacked device structure 10, and some of the features described below may be replaced, modified, or eliminated in other embodiments of stacked device structure 10.

In FIG. 1A and FIG. 1B, device 12U and device 12L each include at least one electrically functional device, such as an upper transistor 20U and a lower transistor 20L, respectively. Stacked device structure 10 thus includes a transistor stack having a top transistor (e.g., transistor 20U) and a bottom transistor (e.g., transistor 20L) separated and/or electrically isolated from one another by insulation structure 16. In some embodiments, transistor 20L and transistor 20U are transistors of an opposite conductivity type. For example, transistor 20L is an n-type transistor, and transistor 20U is a p-type transistor, or vice versa. In such embodiments, transistor 20L and transistor 20U may form a CFET. In some embodiments, transistor 20L and transistor 20U are transistors of a same conductivity type. For example, transistor 20L and transistor 20U may both be n-type transistors or p-type transistors.

Device 12U includes various features and/or components, such as semiconductor layers 26U, semiconductor layers 26M, gate spacers 44, inner spacers 54, epitaxial source/drains 62U, a contact etch stop layer (CESL) 70U, an interlayer dielectric (ILD) layer 72U, a gate dielectric 78U and a gate electrode 80U (collectively referred to as a gate stack 90U), and hard masks 92. Device 12L also includes various features and/or components, such as mesas 14′ (e.g., extensions of substrate 14), semiconductor layers 26L, semiconductor layers 26M, isolation features 32, inner spacers 54, epitaxial source/drains 62L, a CESL 70L, an ILD layer 72L, and a gate dielectric 78L and a gate electrode 80L (collectively referred to as a gate stack 90L). In the depicted embodiment, gate stack 90U is separated and/or electrically isolated from gate stack 90L by insulation structure 17, and gate stack 90U and gate stack 90L are collectively referred to as a gate 90 of stacked device structure 10, such as a metal gate or a high-k/metal gate of a CFET. Further, epitaxial source/drains 62U are separated and/or electrically isolated from epitaxial source/drains 62L by insulation structure 18. In the depicted embodiment, insulation structure 18 is formed from a portion of CESL 70L and ILD layer 72L.

In the depicted embodiment, transistor 20L is a GAA transistor. For example, transistor 20L has two channels provided by semiconductor layers 26L (also referred to as channel layers), which are suspended over substrate 14 and extend between respective source/drains (e.g., epitaxial source/drains 62L). In some embodiments, transistor 20L includes more or less channels (and thus more or less semiconductor layers 26L). Transistor 20L further has gate stack 90L disposed over its semiconductor layers 26L and between its epitaxial source/drains 62L, and inner spacers 54 are disposed between its gate stack 90L and its epitaxial source/drains 62L. Along a gate widthwise direction (e.g., in an X-Z plane), gate stack 90L is over top semiconductor layer 26L, between semiconductor layers 26L, and between bottom semiconductor layer 26L and substrate 14. Along a gate lengthwise direction (e.g., in a Y-Z plane), gate stack 90L wraps around semiconductor layers 26L. During operation of transistor 20L, current may flow through semiconductor layers 26L and between epitaxial source/drains 62L. Semiconductor layers 26M are suspended over substrate 14 and extend between respective insulation structures 18, and insulation structures 17 are disposed between semiconductor layers 26M of device 12L and semiconductor layers 26M of device 12U.

In the depicted embodiment, transistor 20U is also a GAA transistor. For example, transistor 20U has two channels provided by semiconductor layers 26U (also referred to as channel layers), which are suspended over substrate 14 and extend between respective source/drains (e.g., epitaxial source/drains 62U). In some embodiments, transistor 20U includes more or less channels (and thus more or less semiconductor layers 26U). Transistor 20U further has gate stack 90U disposed over its semiconductor layers 26U and between its epitaxial source/drains 62U, gate stack 90U disposed between respective gate spacers 44, inner spacers 54 disposed between its gate stack 90U and its epitaxial source/drains 62U, and hard mask 92 disposed over gate stack 90U. Along a gate widthwise direction, gate stack 90U is over top semiconductor layer 26U, between semiconductor layers 26U, and between bottom semiconductor layer 26U and semiconductor layer 26M. Along a gate lengthwise direction, gate stack 90U wraps around semiconductor layers 26U. During operation of transistor 20U, current may flow through semiconductor layers 26U and between epitaxial source/drains 62U.

Gate spacers 44 are disposed along sidewalls of upper portions of gate stack 90U, inner spacers 54 are disposed under gate spacers 44 along sidewalls of gate stack 90U and/or gate stack 90L, and fin spacers 74 are disposed along sidewalls of mesas 14′. Inner spacers 54 are between semiconductor layers 26 and between bottom semiconductor layers 26 and mesas 14′. Gate spacers 44, inner spacers 54, and fin spacers 74 include a dielectric material.

Gate 90 is disposed between epitaxial source/drain stacks 62, and each epitaxial source/drain stack 62 includes a respective epitaxial source/drain 62U, a respective epitaxial source/drain 62L, and a respective insulation structure (e.g., a respective insulation structure 18) disposed therebetween. Epitaxial source/drains 62L and epitaxial source/drains 62U have the same or different compositions and/or materials depending on configurations of their respective transistors. In some embodiments, epitaxial source/drains 62L and/or epitaxial source/drains 62U include silicon, which may be doped with carbon, phosphorous, arsenic, other n-type dopant, or combinations thereof (e.g., Si:C, Si:P, or Si:C:P). In some embodiments, epitaxial source/drains 62L and/or epitaxial source/drains 62U include silicon germanium or germanium, which may be doped with boron, other p-type dopant, or combinations thereof (e.g., Si:Ge:B). As used herein, source/drain region, epitaxial source/drain, epitaxial source/drain feature, etc. may refer to a source of a device (e.g., transistor 20U and/or transistor 20L), a drain of a device (e.g., transistor 20U and/or transistor 20L), or a source and/or a drain of multiple devices.

Gate dielectric 78U and gate dielectric 78L each include at least one dielectric gate layer, and gate electrode 80U and gate electrode 80L each include at least one electrically conductive gate layer. Gate electrode 80U and gate electrode 80L are disposed over gate dielectric 78U and gate dielectric 78L, respectively. A composition and/or a configuration of gate dielectric 78U may be the same as or different than a composition and/or a configuration of gate dielectric 78L. A composition and/or a configuration of gate electrode 80U may be the same as or different than a composition and/or a configuration of gate electrode 80L.

Source/drain fabrication methods for stacked device structures, such as stacked device structure 10, are disclosed herein. An exemplary method for forming a source/drain stack may include a frontside process and a backside process. The frontside process may include forming a frontside source/drain trench, forming a dummy source/drain in the frontside source/drain trench, and forming an upper source/drain in the frontside source/drain trench over the dummy source/drain. The backside process may include exposing a backside of the dummy source/drain, removing (partially or completely) the dummy source/drain to form a backside source/drain trench, and forming a lower source/drain in the backside source/drain trench. The dummy source/drain may be formed of semiconductor material or dielectric material, and a portion of the dummy source/drain may remain between the upper source/drain and the lower source/drain. In some embodiments, the dummy source/drain is formed inside the backside source/drain trench. In some embodiments, the dummy source/drain is formed inside and outside the backside source/drain trench. In some embodiments, the backside process includes replacing a substrate/mesa with a backside insulation structure and selectively removing the dummy source/drain relative to the backside insulation structure.

Forming the lower source/drain (e.g., via a backside process) after the upper source/drain (e.g., via a frontside process) may improve source/drain stack formation by reducing aspect ratios of source/drain trenches (particularly those associated with forming the lower source/drain), enlarging process windows during frontside processing (e.g., process parameters for forming the dummy source/drain are more flexible than process parameters for forming the lower source/drain, which need to account for dopant profiles and/or dopant concentrations of the lower source/drain), enlarging process windows for forming the lower source/drain (e.g., lower aspect ratio trenches facilitate lower temperature processing and improved control of dopant profiles and/or dopant concentrations), improving source/drain deposition yield (particularly for the lower source/drain), reducing process complexity and/or process time (e.g., by implementing self-aligned deposition and/or self-aligned etching), reducing defects (e.g., epi nodules, which may result from epitaxial growth of a semiconductor material on a dielectric material, and/or voids within a source/drain, which may result from poor epitaxial growth), or combinations thereof. Different embodiments may have different advantages, and no particular advantage is required of any embodiment. Details of the improved fabrication methods for stacked device structures are described further herein.

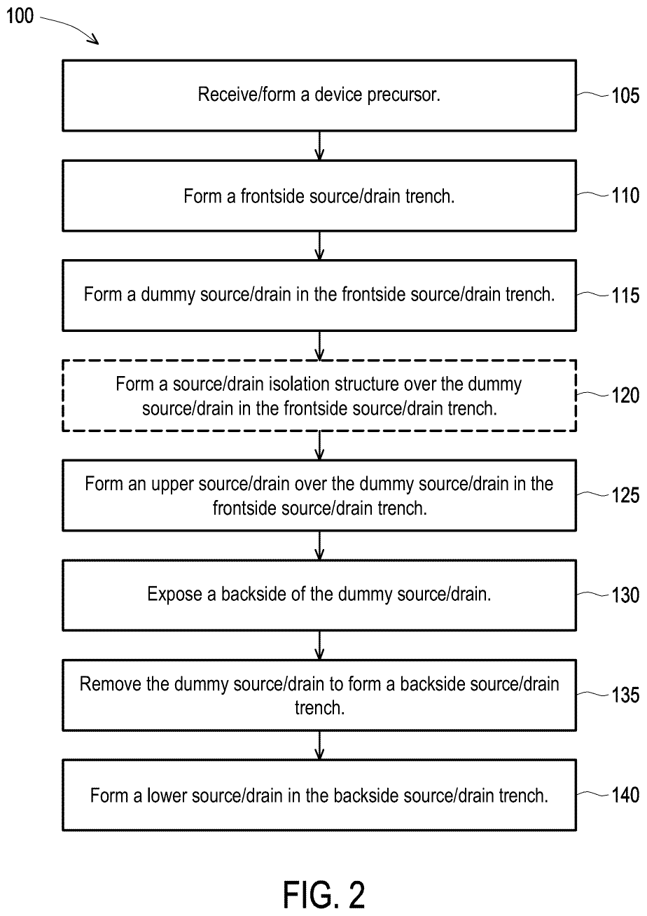

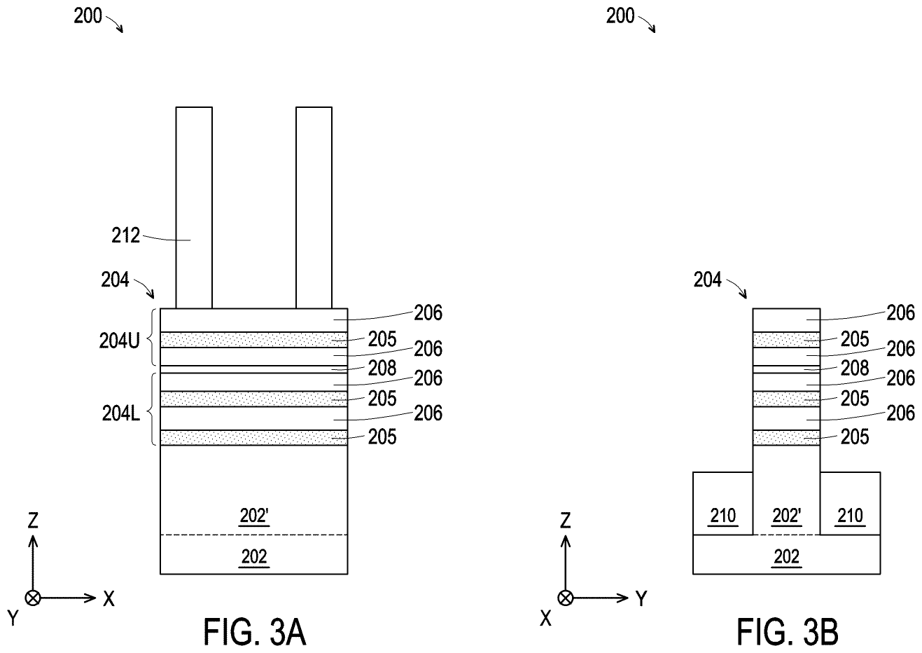

FIG. 2 is a flow chart of a method 100, in portion or entirety, for fabricating source/drains of a stacked device structure, such as stacked device structure 10, according to various aspects of the present disclosure. FIGS. 3A-15A and FIGS. 3B-15B are cross-sectional views of a stacked device structure, such as a stacked device structure 200, in portion or entirety, at various fabrication stages associated with method 100 of FIG. 2 according to various aspects of the present disclosure. FIGS. 3B-15B are taken through source/drain regions of stacked device structure 200 along B-B of FIGS. 3A-15A, respectively. The cross-sectional views of FIGS. 3A-15A and FIGS. 3B-15B are taken (cut) along a gate widthwise direction (e.g., an x-direction) and a gate lengthwise direction (e.g., a y-direction), respectively, and thus, the cross-sectional views may be referred to as x-cut views and y-cut views, respectively. FIG. 2, FIGS. 3A-15A, and FIGS. 3B-15B are discussed concurrently herein for ease of description and understanding. FIG. 2, FIGS. 3A-15A, and FIGS. 3B-15B have been simplified for the sake of clarity to better understand the inventive concepts of the present disclosure. Additional steps may be provided before, during, and after method 100, and some of the steps described may be moved, replaced, or eliminated for additional embodiments of method 100. Additional features may be added in stacked device structure 200, and some of the features described below may be replaced, modified, or eliminated in other embodiments of stacked device structure 200.

Referring to FIG. 2, FIG. 3A, and FIG. 3B, method 100 at block 105 includes receiving and/or forming a device precursor, which may be processed to form source/drains of stacked device structure 200. The device precursor may include a substrate 202, a multilayer projection 204 (depicted as having a mesa 202′ (i.e., a patterned, projecting portion of substrate 202), semiconductor layers 205, semiconductor layers 206, and an intermediate layer 208), a substrate isolation structure 210 over substrate 202, and dummy gates 212.

Substrate 202 includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In the depicted embodiment, substrate 202 is a silicon substrate. In some embodiments, substrate 202 is a semiconductor-on-insulator substrate, such as a silicon-on-insulator (SOI) substrate, a silicon germanium-on-insulator (SGOI) substrate, or a germanium-on-insulator (GOI) substrate. Substrate 202 (and mesa 202′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, other p-type dopant, or combinations thereof. In some embodiments, the doped regions include combinations of p-type dopants and n-type dopants. The doped regions may be formed directly on and/or in substrate 202, for example, providing a p-well structure, an n-well structure, a dual-well structure, a raised structure, other suitable structure, or combinations thereof. In some embodiments, substrate 202 and/or mesa 202′, and semiconductor layers thereover may include an n-well and/or a p-well.

Multilayer projection 204 extends along an x-direction, having a length along the x-direction, a width along a y-direction, and a height along a z-direction. In some embodiments, multilayer projection 204 includes mesa 202′, a lower semiconductor stack 204L, an upper semiconductor stack 204U, and intermediate layer 208. Lower semiconductor stack 204L is disposed over mesa 202′, intermediate layer 208 is disposed over lower semiconductor stack 204L, and upper semiconductor stack 204U is disposed over intermediate layer 208. Upper semiconductor stack 204U and lower semiconductor stack 204L each include semiconductor layers 205 and semiconductor layers 206, which are stacked vertically (e.g., along the z-direction) in an interleaving or alternating configuration from a top surface of substrate 202. In some embodiments, multilayer projection 204 is a fin and/or a fin active region.

A composition of semiconductor layers 205, a composition of semiconductor layers 206, and a composition of intermediate layer 208 are different to achieve etching selectivity and/or different oxidation rates during processing. For example, semiconductor layers 205, semiconductor layers 206, and intermediate layer 208 include different materials, constituent atomic percentages, constituent weight percentages, thicknesses, other characteristics, or combinations thereof to achieve etching selectivity. In some embodiments, semiconductor layers 206 include silicon, semiconductor layers 205 include silicon germanium having a first germanium atomic percent, and intermediate layer 208 includes silicon germanium having a second germanium atomic percent that is different than the first germanium atomic percent. With such compositions, semiconductor layers 205 may have a first etch rate to an etchant, semiconductor layers 206 may have a second etch rate to the etchant, and intermediate layer 208 may have a third etch rate to the etchant, where the first etch rate, the second etch rate, and the third etch rate are different. In some embodiments, semiconductor layers 206 include silicon germanium having a third germanium atomic percent that is different than the first germanium atomic percent and the second germanium atomic percent. In some embodiments, semiconductor layers 206 of upper semiconductor stack 204U and lower semiconductor stack 204L have a same composition (e.g., silicon). In some embodiments, semiconductor layers 206 of upper semiconductor stack 204U and semiconductor layers 206 of lower semiconductor stack 204L have different compositions (e.g., silicon and silicon germanium, respectively). The present disclosure contemplates semiconductor layers 205, semiconductor layers 206, and intermediate layer 208 having any combination of semiconductor materials that provides desired etching selectivity, desired oxidation rate differences, desired performance characteristics (e.g., materials that maximize current flow), or combinations thereof.

Substrate isolation structure 210 electrically isolates active device regions and/or passive device regions from one another. For example, substrate isolation structure 210 separates and electrically isolates an active region of stacked device structure 200 from other device regions. Substrate isolation structure 210 includes silicon oxide, silicon nitride, silicon oxynitride, other suitable isolation material (including, for example, silicon, oxygen, nitrogen, carbon, other suitable isolation constituent, etc.), or a combination thereof. Substrate isolation structure 210 may have a multilayer structure. For example, substrate isolation structure 210 may include a bulk dielectric (e.g., an oxide layer) over a dielectric liner (including, for example, silicon nitride, silicon oxide, silicon oxynitride, silicon oxycarbonitride, or combinations thereof). In another example, substrate isolation structure 210 may include a dielectric layer over a doped liner, such as a boron silicate glass (BSG) liner and/or a phosphosilicate glass (PSG) liner. Dimensions and/or characteristics of substrate isolation structure 210 are configured to provide a shallow trench isolation (STI) structure, a deep trench isolation (DTI) structure, a local oxidation of silicon (LOCOS) structure, other suitable isolation structure, or combinations thereof. In the depicted embodiment, substrate isolation structure 210 may be an STI.

Dummy gates 212 extend lengthwise in a direction that is different than (e.g., orthogonal to) the lengthwise direction of multilayer projection 204. For example, dummy gates 212 extend along the y-direction, having a length in the y-direction, a width in the x-direction, and a height in the z-direction. Each dummy gate 212 may be disposed over a respective channel region of multilayer projection 204 and between respective source/drain regions of multilayer projection 204. In the Y-Z plane, dummy gates 212 may be disposed on a top and sidewalls of channel regions of multilayer projection 204, and dummy gates 212 may wrap channel regions of multilayer projection 204. Dummy gates 212 may also be disposed over tops of substrate isolation structures 210. In the X-Z plane, dummy gates 212 may be disposed over tops of channel regions of multilayer projection 204, and dummy gates 212 may be disposed between source/drain regions of multilayer projection 204. In the depicted embodiment, a source/drain region of multilayer projection 204 is disposed between dummy gates 212.

Dummy gates 212 may include a dummy gate dielectric, a dummy gate electrode, and a hard mask (which may have a multilayer structure). The dummy gate dielectric includes a dielectric material, such as silicon oxide, a high-k dielectric material, other suitable dielectric material, or combinations thereof. For example, the dummy gate dielectric is an oxide layer. The dummy gate electrode includes a suitable dummy gate material, such as polysilicon.

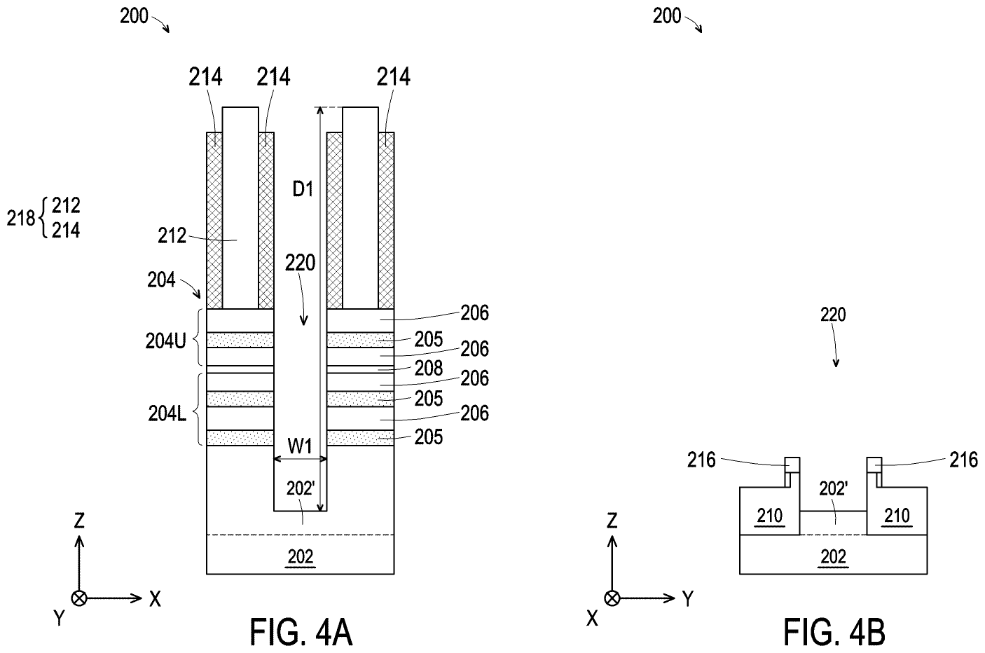

Referring to FIG. 2, FIG. 4A, and FIG. 4B, method 100 at block 110 includes forming a frontside source/drain trench (recess). For example, a source/drain trench 220 is formed in the source/drain region of multilayer projection 204. Source/drain trench 220 may be formed by applying an etching process to a frontside of stacked device structure 200. The etching process partially removes portions of multilayer projection 204 that are not covered by dummy gates 212 (i.e., source/drain regions thereof). For example, the etching process may remove upper semiconductor stack 204U, intermediate layer 208, and lower semiconductor stack 204L in the source/drain region of multilayer projection 204, thereby exposing mesa 202′. The etching process may further remove some, but not all, of mesa 202′, such that source/drain trench 220 extends below a top surface of substrate isolation structure 210. The etching process is a dry etch, a wet etch, other suitable etch, or combinations thereof. In some embodiments, the etching process is a multistep etch process. In some embodiments, parameters of the etching process (e.g., etchant thereof) are configured to selectively remove semiconductor materials (i.e., multilayer projection 204) with negligible removal of dielectric materials (e.g., hard mask of dummy gates 212, gate spacers, fin spacers, substrate isolation structure 210, etc.).

Gate spacers 214 and fin spacers 216 may be formed before, during, or after forming source/drain trench 220. For example, forming gate spacers 214 and fin spacers 216 may include depositing a spacer layer (e.g., silicon and nitrogen, such as a silicon nitride layer) over stacked device structure 200 and etching the spacer layer to form gate spacers 214 and fin spacers 216. In such example, the spacer layer may be deposited before forming source/drain trench 220 and the etching process used to form source/drain trench 220 may also be used to remove portions of the spacer layer to form gate spacers 214 and/or fin spacers 216. In some embodiments, the etching process used to remove portions of the spacer layer to form gate spacers 214 and/or fin spacers 216 may slightly recess and/or etch back substrate isolation structure 210. In some embodiments, gate spacers 214 and fin spacers 216 are formed simultaneously. In some embodiments, gate spacers 214 and fin spacers 216 are formed separately.

Gate spacers 214 are disposed adjacent to and along sidewalls of dummy gates 212, and fin spacers 216 are disposed adjacent to and along sidewalls of source/drain regions of multilayer projection 204 (e.g., along sidewalls of mesa 202′). Gate spacers 214 and dummy gates 212 may combine to provide gate structures 218, where each gate structure 218 includes a respective dummy gate 212 and respective gate spacers 214. Gate spacers 214 and fin spacers 216 each includes a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 214 and/or fin spacers 216 have a multilayer structure, such as a first dielectric layer (e.g., a silicon nitride layer) and a second dielectric layer (e.g., a silicon carbide layer). In some embodiments, gate spacers 214 and/or fin spacers 216 include more than one set of spacers, such as seal spacers, offset spacers, sacrificial spacers, dummy spacers, main spacers, or combinations thereof. In such embodiments, the various sets of spacers may have different compositions.

In the X-Z plane (e.g., FIG. 4A), source/drain trench 220 has respective sidewalls formed by multilayer projection 204 and a bottom formed by mesa 202′. In the Y-Z plane (e.g., FIG. 4B), source/drain trench 220 has respective sidewalls formed by fin spacers 216 and substrate isolation structure 210 and a bottom formed by mesa 202′. Source/drain trench 220 has a width W1 along the x-direction, and a depth D1 (along the z-direction) is between tops of dummy gates 212 and a bottom of source/drain trench 220. Depth D1 is greater than width W1. For example, width W1 may be less than about 20 nm, and depth D1 may be about 200 nm to about 300 nm. As stacked device structures are implemented in scaled IC technology nodes, increasing structure heights (e.g., greater fin/active region heights, which may result from multilayer projection 204 having upper semiconductor stack 204U and lower semiconductor stack 204L to process to provide an upper transistor and a lower transistor, respectively) and decreasing dimensions (e.g., ever smaller gate pitches that correspondingly reduce source/drain trench widths between gates) has led to high aspect ratio (e.g., having depths D1 that are much greater than width W1) openings between dummy gates 212 that present process challenges. In some embodiments, an aspect ratio of openings between dummy gates 212 (e.g., a ratio of depth D1 to width W1) after forming source/drain trench(es) 220 may be greater than 10, which has been observed to hinder and/or degrade lower source/drain formation. For example, where the lower source/drain has a multilayer structure, the higher aspect ratio opening makes it difficult to control a thickness of each source/drain layer. As another example, higher temperature processing may be needed to improve lower source/drain fabrication throughput, but such higher temperature processing is limited by dopant profile and/or dopant concentration limits of the lower source/drain (e.g., the higher temperature processing needs to be configured to limit and/or prevent diffusion of dopant from the lower source/drain into semiconductor layers 206). In yet another example, the higher aspect ratio opening may promote formation of source/drain defects, such as voids in the lower source/drain, which may result from poor epitaxial growth in a bottom of the higher aspect ratio opening, and/or epi nodules, which may result from undesired epitaxial growth of a semiconductor material on a dielectric material when a deposition process is configured to ensure adequate bottom epitaxial growth in the higher aspect ratio opening.

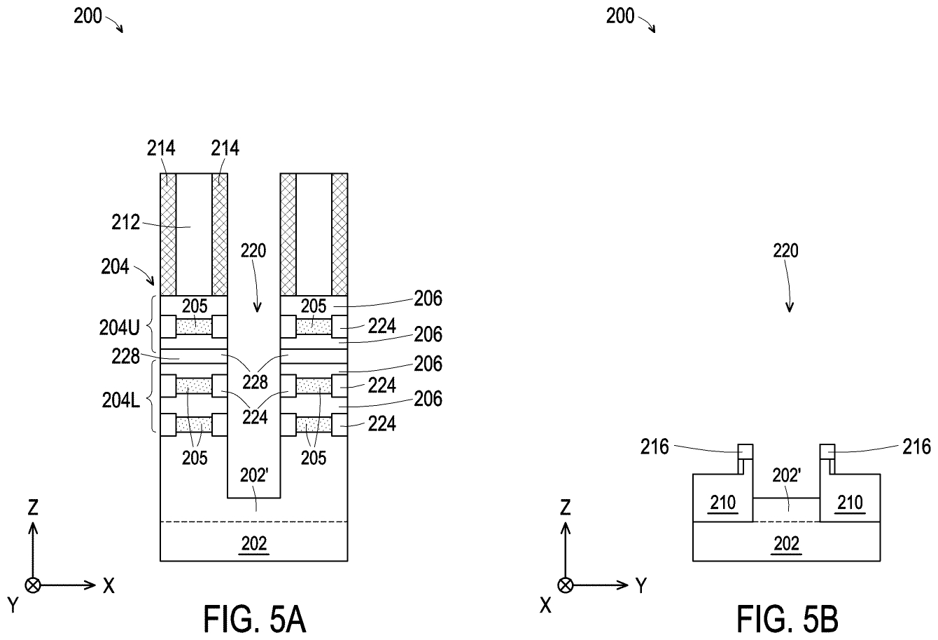

Referring to FIG. 5A and FIG. 5B, processing may include forming inner spacers 224 under gate spacers 214 along sidewalls of semiconductor layers 205 and replacing intermediate layer 208 with an insulation layer 228. Inner spacers 224 separate semiconductor layers 206 from one another and bottom semiconductor layers 206 from mesas 202′, while insulation layer 228 separates upper semiconductor stack 204U from lower semiconductor stack 204L. Inner spacers 224 may replace portions of semiconductor layers 205 under gate spacers 214.

Forming inner spacers 224 and insulation layer 228 may include a first etching process, a deposition process, and a second etching process. The first etching process may selectively etch semiconductor layers 205 and intermediate layer 208 with negligible etching of semiconductor layers 206, mesas 202′, substrate isolation structure 210, dummy gates 212, gate spacers 214, fin spacers 216, or combinations thereof. The first etching process is configured to laterally etch (e.g., along the x-direction and/or the y-direction) semiconductor layers 205. Accordingly, the first etching process forms gaps between semiconductor layers 206, gaps between mesas 202′ and semiconductor layers 206, and gaps between upper semiconductor stack 204U and lower semiconductor stack 204L. Because semiconductor layers 205 and intermediate layer 208 have different compositions (e.g., different germanium concentrations), parameters of the first etching process may be configured to completely remove intermediate layer 208 and partially remove semiconductor layers 205. For example, an etchant of the first etching process may remove intermediate layer 208 (e.g., SiGe having the second germanium atomic percent) faster than semiconductor layers 205 (e.g., SiGe having the first germanium atomic percent). A ratio of a first etch rate to the second etch rate may be tuned to simultaneously remove intermediate layer 208 and semiconductor layers 205, yet completely remove intermediate layer 208 while partially removing semiconductor layers 205. The first etching process is a dry etch, a wet etch, other suitable etch, or combinations thereof. In some embodiments, the first etching process is an anisotropic etch having a horizontal etch rate greater than a vertical etch rate (e.g., the vertical etch rate may be zero), and the anisotropic etch may remove material in substantially the horizontal direction with negligible material removal in the vertical direction.

The deposition process may form an insulation material over stacked device structure 200, and the deposition process may be configured to fill the gaps between semiconductor layers 206, the gaps between mesas 202′ and semiconductor layers 206, and the gaps between upper semiconductor stack 204U and lower semiconductor stack 204L with the insulation material. The second etching process selectively etches the insulation material to form inner spacers 224 and insulation layer 228 with negligible etching of semiconductor layers 206, mesas 202′, substrate isolation structure 210, dummy gates 212, gate spacers 214, fin spacers 216, or combinations thereof. To achieve desired etching selectivity during the second etching process, the insulation material (and thus inner spacers 224 and insulation layer 228) has a composition different than compositions of semiconductor layers 206, mesas 202′, substrate isolation structure 210, dummy gates 212, gate spacers 214, fin spacers 216, or combinations thereof. In some embodiments, the insulation material includes a dielectric material that includes silicon, oxygen, carbon, nitrogen, other suitable dielectric constituent, or combinations thereof. For example, the insulation material is silicon nitride, silicon carbonitride, silicon oxycarbonitride, silicon oxycarbide, other suitable material, or combinations thereof. The second etching process is a dry etch, a wet etch, other suitable etch, or combinations thereof.

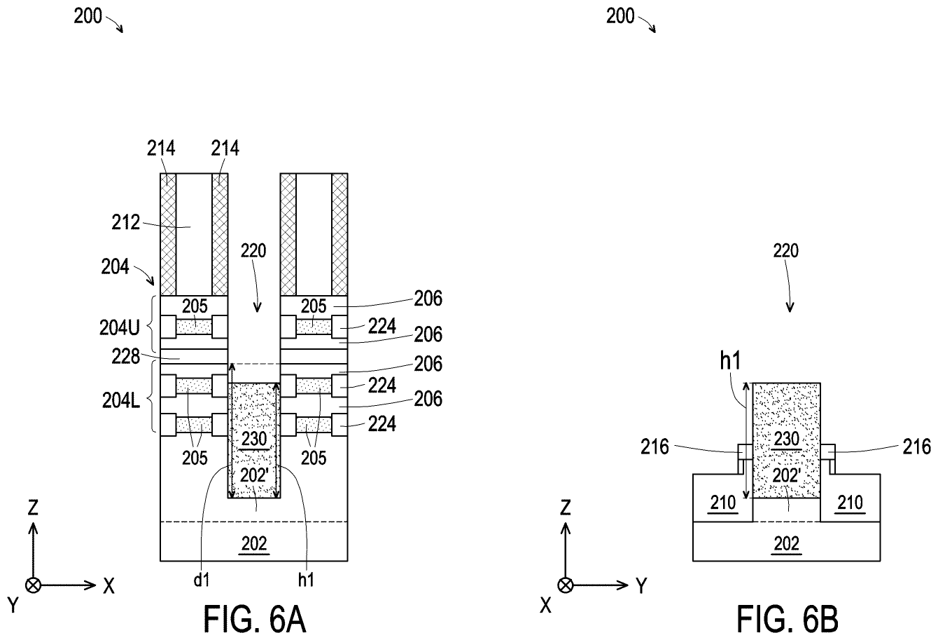

Referring to FIG. 2, FIG. 6A, and FIG. 6B, method 100 at block 115 includes forming a dummy source/drain in the frontside source/drain trench. For example, a dummy source/drain 230 is formed in and partially fills source/drain trench 220. A height h1 of dummy source/drain 230 is less than depth D1. Height h1 is also less than a distance d1 between a top of lower semiconductor stack 204L (and/or a bottom of insulation layer 228) and a bottom of source/drain trench 220. In other words, dummy source/drain 230 is below insulation layer 228. In the depicted embodiment, dummy source/drain 230 is below a topmost semiconductor layer 206 of lower semiconductor stack 204L (and/or a top of topmost semiconductor layer 205 of lower semiconductor stack 204L). In some embodiments, height h1 is about 40 nm to about 80 nm. In some embodiments (see, e.g., FIG. 6B), dummy source/drain 230 is confined to source/drain trench 220, and dummy source/drain 230 does not extend laterally over substrate isolation structure 210 and/or extend laterally over and/or beyond fin spacers 216.

A composition of dummy source/drain 230 is different than a composition of mesa 202′, a composition of semiconductor layers 205, a composition of semiconductor layers 206, a composition of inner spacers 224, a composition of a subsequently formed backside dielectric layer, or combinations thereof to facilitate selective etching/removal therebetween. In the depicted embodiment, dummy source/drain 230 includes a semiconductor material that is different than the semiconductor materials of mesa 202′, semiconductor layers 205, and semiconductor layers 206. For example, where mesa 202′ is formed of silicon, semiconductor layers 206 are formed of silicon, and semiconductor layers 205 are formed of silicon germanium having a first germanium content, dummy source/drain 230 may be formed of germanium or silicon germanium having a second germanium content that is different than the first germanium content. In some embodiments, dummy source/drain 230 is a dummy Ge source/drain. In some embodiments, dummy source/drain 230 is a dummy Si₁₋ₓGeₓ source/drain, where x is about 0.1 to about 1 (i.e., 0.1≤x≤1). If x=0, etch selectivity needed during subsequent processing may not be provided between dummy source/drain 230 and semiconductor layers 205, semiconductor layers 206, mesa 202′, or combinations thereof depending on their compositions.

Dummy source/drain 230 is formed by depositing a semiconductor material in source/drain trench 220. The semiconductor material fills at least a lower portion of source/drain trench 220, such as a portion thereof that corresponds with a lower device level of stacked device structure 200 (e.g., below insulation layer 228). In some embodiments, a selective deposition process deposits/forms the semiconductor material inside source/drain trench 220 but not outside source/drain trench 220 (e.g., over substrate isolation structure 210 and/or fin spacers 216). In some embodiments, an epitaxy process epitaxially grows the semiconductor material from substrate 202, mesa 202′, semiconductor layers 206, or combinations thereof, thereby forming a dummy epitaxial source/drain. The epitaxy process may use chemical vapor deposition (CVD) deposition techniques (e.g., remote plasma CVD (RPCVD), low pressure CVD (LPCVD), vapor phase epitaxy (VPE), ultrahigh vacuum CVD (UHV-CVD), or combinations thereof), molecular beam epitaxy (MBE), other suitable epitaxy process, or combinations thereof. The epitaxy process may use gaseous precursors and/or liquid precursors, which may interact with and/or adsorb on compositions of substrate 202, mesa 202′, semiconductor layers 206, or combinations thereof, but not interact with compositions of inner spacers 224, insulation layer 228, gate spacers 214, fin spacers 216, substrate isolation structure 210, or combinations thereof.

Forming dummy source/drain 230 may also include etching back the semiconductor material. The etching back may remove semiconductor material that forms/deposits in an upper portion of source/drain trench 220, such as a portion thereof that corresponds with an upper device level of stacked device structure 200 (e.g., above insulation layer 228). In some embodiments, a height of the semiconductor material after deposition is greater than height h1 (e.g., the semiconductor material may fill the lower portion of source/drain trench 220 and at least partially fill the upper portion of source/drain trench 220), and the etching back may reduce the height of the semiconductor material to a height that is less than distance d1 (i.e., the semiconductor material remaining after the etch back is below insulation layer 228). In some embodiments, the etching back reduces the height of the semiconductor material to height h1 (e.g., below topmost semiconductor layer 206 of lower semiconductor stack 204L). The etching back may selectively remove/etch the semiconductor material with negligible removal/etching of semiconductor layers 206, substrate isolation structure 210, dummy gates 212, gate spacers 214, fin spacers 216, inner spacers 224, insulation layer 228, or combinations thereof. The etching back is a dry etch, a wet etch, other suitable etch, or combinations thereof.

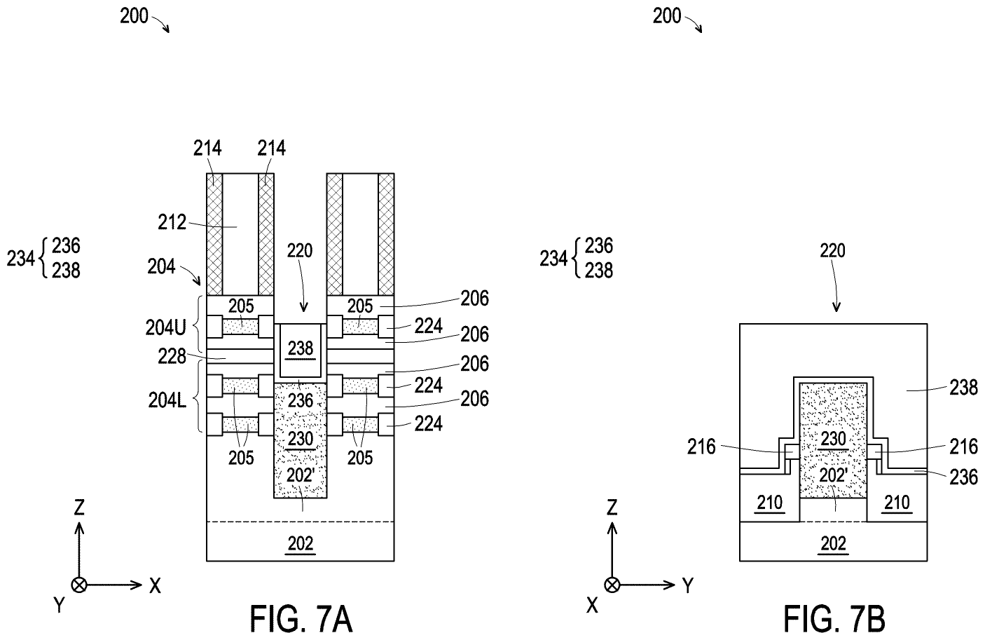

Referring to FIG. 2, FIG. 7A, and FIG. 7B, method 100 at block 120 includes forming a source/drain isolation structure over the dummy source/drain in the frontside source/drain trench. For example, a dielectric layer 234 is formed over dummy source/drain 230 in source/drain trench 220. Dielectric layer 234 partially fills source/drain trench 220, and dielectric layer 234 may wrap dummy source/drain 230 (see, e.g., FIG. 7B). Dielectric layer 234 is below semiconductor layers 206 of upper semiconductor stack 204U that will provide channels of upper transistors, above semiconductor layers 206 of lower semiconductor stack 204L that will provide channels of lower transistors, and adjacent to semiconductor layers 206 of upper semiconductor stack 204U and lower semiconductor stack 204L that will provide dummy channels of upper transistors and lower transistors, respectively (i.e., electrically inactive portions and/or not electrically functioning components thereof). For example, dielectric layer 234 is below top semiconductor layer 206 of upper semiconductor stack 204U, which will provide channels for upper transistors, adjacent to bottom semiconductor layer 206 of upper semiconductor stack 204U, which will provide dummy channels of upper transistors, above bottom semiconductor layer 206 of lower semiconductor stack 204U, which will provide channels for lower transistors, and adjacent to top semiconductor layer 206 of lower semiconductor stack 204L, which will provide dummy channels of lower transistors.

Dielectric layer 234 may have a multilayer structure, such as a CESL 236 and an ILD layer 238. In some embodiments, forming dielectric layer 234 includes depositing CESL 236 over dummy source/drain 230, depositing ILD layer 238 over CESL 236, and etching back ILD layer 238 and CESL 236 below a bottom of lowest channel layers of the upper device level of stacked device structure 200 (e.g., below top semiconductor layers 206 of upper semiconductor stack 204U). CESL 236 and ILD layer 238 are formed by CVD, other suitable methods, or combinations thereof. CESL 236 and/or ILD layer 238 may be formed/deposited inside source/drain trench 220 and outside source/drain trench 220, such that CESL 236 and/or ILD layer 238 are formed over/on substrate isolation structure 210 and fin spacers 216. In some embodiments, ILD layer 238 is formed by flowable CVD (FCVD), high aspect ratio (HAR) deposition, high density plasma CVD (HDPCVD), or combinations thereof.

ILD layer 238 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or combinations thereof. In some embodiments, ILD layer 238 includes a low-k dielectric material having a dielectric constant that is less than a dielectric constant of silicon dioxide (e.g., k<3.9). In some embodiments, ILD layer 238 includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which is tuned/configured to exhibit a dielectric constant less than about 2.5. ILD layer 238 may have a multilayer structure that includes multiple dielectric materials. CESL 236 includes a material different than ILD layer 238, such as a dielectric material that is different than the dielectric material of ILD layer 238. For example, where ILD layer 238 includes a silicon-and-oxygen comprising low-k dielectric material, CESL 236 may include silicon and nitrogen, such as silicon nitride or silicon oxynitride.

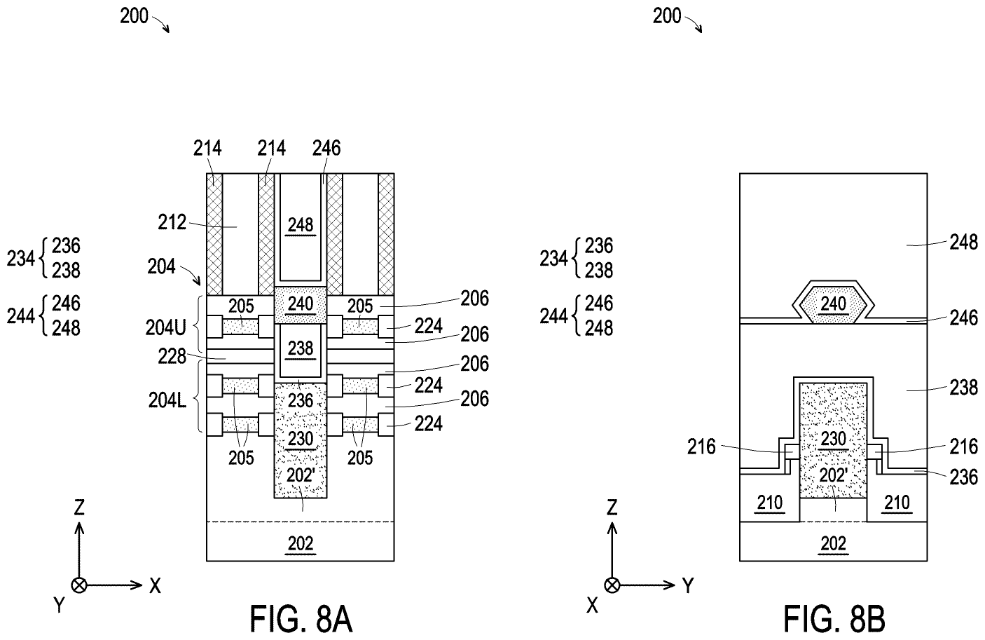

Referring to FIG. 2, FIG. 8A, and FIG. 8B, method 100 at block 125 includes forming an upper source/drain over the dummy source/drain in the frontside source/drain trench. For example, upper source/drain 240 is formed over dummy source/drain 230. In the depicted embodiment, upper source/drain 240 is further formed over dielectric layer 234 (i.e., the source/drain isolation structure), and upper source/drain 240 fills a remainder of source/drain trench 220. Upper source/drain 240 is disposed between and adjacent to semiconductor layers 206 of upper semiconductor stack 204U, which will provide channels of upper transistors (here, top semiconductor layers 206 of upper semiconductor stack 204), and upper source/drain 240 provides a source/drain for upper transistors of stacked device structure 200.

In the depicted embodiment, the upper transistors of stacked device structure 200 are n-type transistors, and upper source/drain 240 is configured for n-type transistors. For example, upper source/drain 240 includes silicon doped with carbon, phosphorous, arsenic, other n-type dopant, or combinations thereof. In such example, upper source/drain 240 may be an Si:C epitaxial source/drain, an Si:P epitaxial source/drain, or an Si:C:P epitaxial source/drain. In some embodiments, a concentration of phosphorous in upper source/drain 240 (e.g., an Si:P epitaxial source/drain or an Si:C:P epitaxial source/drain) is greater than about 1×10²¹ atoms/cm³. In some embodiments, the upper transistors of stacked device structure 200 are p-type transistors, and upper source/drain 240 is configured for p-type transistors. For example, upper source/drain 240 includes silicon germanium or germanium doped with boron, other p-type dopant, or combinations thereof. In such example, upper source/drain 240 may be an Si:Ge:B epitaxial source/drain. In some embodiments, a concentration of boron in upper source/drain 240 (e.g., an Si:Ge:B epitaxial source/drain) is greater than about 5×10²⁰ atoms/cm³. In some embodiments, upper source/drain 240 has a multilayer structure. For example, upper source/drain 240 may include semiconductor layers having different compositions, and the different compositions may be achieved by configuring the semiconductor layers with different semiconductor materials, different dopants, different atomic percentages of constituents thereof, different dopant concentrations, or combinations thereof.

Upper source/drain 240 may be formed by an epitaxy process. The epitaxy process may include epitaxially growing semiconductor material from exposed semiconductor layers 206 that fills the remainder of source/drain trench 220. The epitaxy process may use CVD deposition techniques (e.g., RPCVD, LPCVD, VPE, UHV-CVD, or combinations thereof), MBE, other suitable epitaxy process, or combinations thereof. The epitaxy process may use gaseous precursors and/or liquid precursors, which may interact with and/or adsorb on the composition of semiconductor layers 206, but not interact with compositions of inner spacers 224, gate spacers 214, CESL 236, ILD layer 238, or combinations thereof. In some embodiments, upper source/drain 240 is doped during deposition (i.e., in-situ), for example, by adding dopant to a source material of the epitaxy process. In some embodiments, upper source/drain 240 is doped after deposition thereof, for example, by an ion implantation process. In some embodiments, annealing processes (e.g., rapid thermal annealing and/or laser annealing) are performed to activate dopants in upper source/drain 240. In some embodiments, upper source/drain 240 includes materials and/or dopants that achieve desired tensile stress and/or compressive stress in channel regions (e.g., semiconductor layers 206) of the upper transistors.

In some embodiments, after forming upper source/drain 240, a dielectric layer 244 is formed over stacked device structure 200. Dielectric layer 244 is disposed over upper source/drain 240, and dielectric layer 244 may wrap upper source/drain 240 (see, e.g., FIG. 8B). In the X-Z plane, dielectric layer 244 fills spaces between adjacent gate structures, such as gaps between gate spacers 214 of adjacent gate structures 218. In the depicted embodiment, dielectric layer 244 has a multilayer structure, such as a CESL 246, which may be similar to CESL 236, and an ILD layer 248, which may be similar to ILD layer 238. In some embodiments, forming dielectric layer 244 includes depositing CESL 246 over stacked device structure 200, depositing ILD layer 248 over CESL 246, and performing a CMP and/or other planarization process until reaching (exposing) dummy gates 212. In some embodiments, the planarization process removes a hard mask, or portion thereof, of dummy gates 212. In some embodiments, the planarization process exposes dummy gate electrodes (e.g., poly gates) of dummy gates 212.

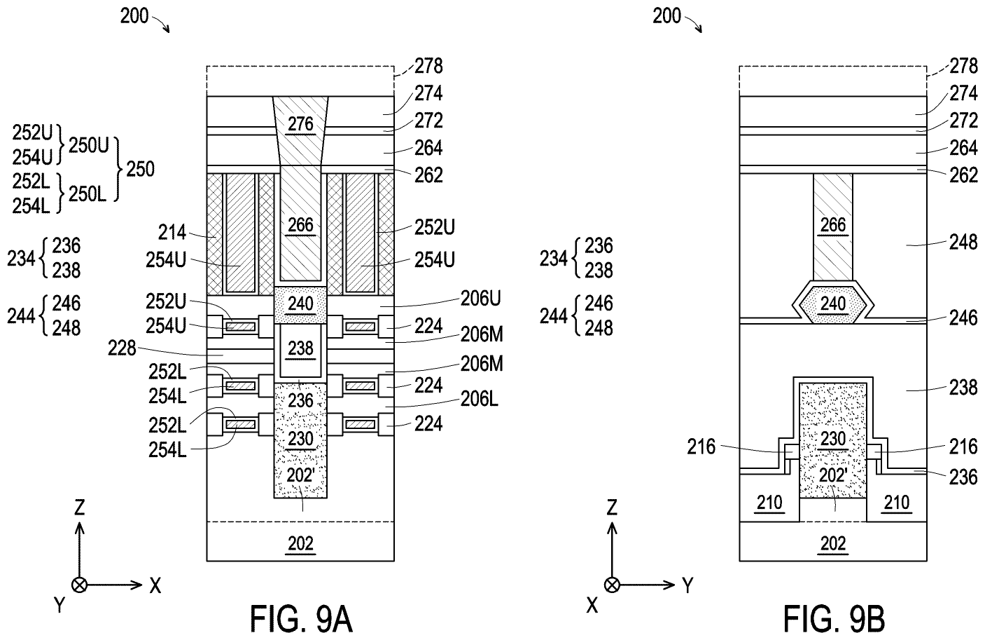

Referring to FIG. 9A and FIG. 9B, processing may further include performing a gate replacement process (RPG), which replaces dummy gates 212 (and semiconductor layers 205) with gate stacks 250. In the depicted embodiment, each gate stack 250 has a respective upper gate 250U, which is disposed between respective upper source/drains (e.g., upper source/drains 240), and a respective lower gate 250L, which is disposed between respective lower source/drains (e.g., dummy source/drains 230). Upper gate 250U includes a gate dielectric 252U and a gate electrode 254U, and lower gate 250L includes a gate dielectric 252L and a gate electrode 254L. Upper gate 250U is disposed between gate spacers 214, between inner spacers 224, and between semiconductor layers 206. Lower gate 250L is disposed between inner spacers 224, between semiconductor layers 206, and between semiconductor layers 206 and mesas 202′. Upper gate 250U may surround and/or wrap semiconductor layers 206 above insulation layer 228 (e.g., in the Y-Z plane), and lower gate 250L may surround and/or wrap semiconductor layers 206 below insulation layer 228 (e.g., in the Y-Z plane).

Gate dielectric 252U and gate dielectric 252L each include at least one dielectric gate layer. A composition and/or a configuration of gate dielectric 252U may be the same as or different than a composition and/or a configuration of gate dielectric 252L. In some embodiments, gate dielectric 252U and gate dielectric 252L each include an interfacial layer that includes a dielectric material, such as SiO₂, SiGeOₓ, HfSiO, SiON, other dielectric material, or combinations thereof. In some embodiments, gate dielectric 252U and gate dielectric 252L each include a high-k dielectric layer. The high-k dielectric layer includes a high-k dielectric material, which generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TIO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, other high-k dielectric material, or combinations thereof. For example, gate dielectric 252U and gate dielectric 252L may each include a hafnium-based oxide (e.g., HfO₂) layer and/or a zirconium-based oxide (e.g., ZrO₂) layer. In some embodiments, the interfacial layer and/or the high-k dielectric layer has a multilayer structure.

Gate electrode 254U and gate electrode 254L are disposed over gate dielectric 252U and gate dielectric 252L, respectively. A composition and/or a configuration of gate electrode 254U may be the same as or different than a composition and/or a configuration of gate electrode 254L. Gate electrode 254U and gate electrode 254L each include at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, gate electrode 254U and/or gate electrode 254L include a work function layer. The work function layer is a conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAIN, or combinations thereof. In some embodiments, gate electrode 254U and/or gate electrode 254L include a bulk layer over the gate dielectric and/or the work function layer. The bulk layer includes a suitable conductive material, such as Al, W, Cu, Ti, Ta, TiN, TaN, polysilicon, other suitable metal(s) and/or alloys thereof, or combinations thereof. In some embodiments, gate electrode 254U and/or gate electrode 254L include a barrier (blocking) layer over the work function layer and/or the gate dielectric. The barrier layer includes a material that prevents or eliminates diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

In some embodiments, the gate replacement process includes removing dummy gates 212 to form gate openings in gate structures 218, depositing gate dielectric layers that partially fill the gate openings, depositing gate electrode layers that fill remainders of the gate openings, and performing a planarization process to remove portions of the gate dielectric layers and/or portions of the gate electrode layers over dielectric layer 244. The gate replacement process may form upper gate 250U and lower gate 250L simultaneously, separately, or at least partially simultaneously. In some embodiments, a channel release process is performed after removing dummy gates 212 and before forming gate stacks 250 to provide suspended channel layers (e.g., semiconductor layers 206) in channel regions. The channel release process may include selectively removing semiconductor layers 205 exposed by the gate openings to form gaps between semiconductor layers 206 and gaps between semiconductor layers 206 and mesas 202′. The gate dielectric layers and/or the gate electrode layers may then be deposited/formed in and fill the gaps, such that the gate dielectric layers and/or the gate electrode layers may form around semiconductor layers 206. In the depicted embodiment, four semiconductor layers 206 are vertically stacked along the z-direction, topmost semiconductor layer 206 provides a channel through which current may flow between upper source/drains (e.g., upper source/drains 240), bottommost semiconductor layer 206 provides a channel through which current may flow between lower source/drains, and middle semiconductor layers 206 provide dummy channels. Semiconductor layers 206 may thus be referred to as semiconductor layer 206U (e.g., a channel layer of upper transistors), semiconductor layers 206M (e.g., dummy channel layers), and semiconductor layer 206L (e.g., a channel layer of lower transistors).

In some embodiments, processing may further include etching back upper gates 250U and forming hard masks (e.g., self-aligned cap (SAC) structures), such as hard masks 92, over the etched-back upper gates 250U. The hard masks include a material that is different than dielectric layer 244 and/or subsequently formed dielectric layers to achieve etch selectivity. In some embodiments, the hard masks include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, the hard masks include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or combinations thereof.

In some embodiments, the channel release process includes an etching process that selectively removes semiconductor layers 205 with respect to semiconductor layers 206, mesas 202′, gate spacers 214, inner spacers 224, insulation layer 228, dielectric layer 244, or combinations thereof. For example, the etching process etches semiconductor layers 205 with no (or negligible) etching of semiconductor layers 206, mesas 202′, gate spacers 214, inner spacers 224, insulation layer 228, dielectric layer 244, or combinations thereof. An etchant of the etching process may etch silicon germanium (i.e., semiconductor layers 205) at a higher rate than silicon (i.e., semiconductor layers 206) and dielectric materials (i.e., gate spacers 214, inner spacers 224, insulation layer 228, dielectric layer 244, etc.). In some embodiments, semiconductor layers 205 have a germanium concentration that is less than about 10% to about 35%, and the germanium concentration may be less than a germanium concentration of upper source/drain 240, in some embodiments. The etching process is a dry etch, a wet etch, other suitable etching process, or combinations thereof. In some embodiments, before performing the etching process, an oxidation process converts semiconductor layers 205 into semiconductor oxide features (e.g., silicon germanium oxide), and the etching process then removes the semiconductor oxide features. In some embodiments, during and/or after removing semiconductor layers 205, an etching process is performed to modify a profile of semiconductor layers 206 to achieve target dimensions and/or target shapes for channels of stacked device structure 200, such as cylindrical-shaped channel layers (e.g., nanowires), rectangular-shaped channel layers (e.g., nanobars), sheet-shaped channel layers (e.g., nanosheets), etc.

Processing may further include forming a frontside, upper source/drain interconnect to upper source/drain 240, which may include forming a first dielectric layer (e.g., a CESL 262 and an ILD layer 264) over dielectric layer 244, forming a source/drain contact opening in the first dielectric layer that exposes upper source/drain 240, forming a source/drain contact 266 in the source/drain contact opening, forming a second dielectric layer (e.g., a CESL 272 and an ILD layer 274) over the first dielectric layer, forming a source/drain via opening in the second dielectric layer that exposes source/drain contact 266, and forming a source/drain via 276 in the second dielectric layer. In some embodiments, a silicidation process is performed to form an upper silicide layer over upper source/drain 240 before forming source/drain contact 266.

In some embodiments, forming source/drain contact 266 includes depositing at least one electrically conductive material (e.g., a metal bulk material) over the first dielectric layer that fills the source/drain contact opening and performing a planarization process to remove any of the at least one electrically conductive material that is disposed over a top of the first dielectric layer. The planarization process may be performed until reaching and exposing ILD layer 264. Remainders of the electrically conductive material form metal plugs and, in some embodiments, metal liners of source/drain contact 266. In some embodiments, forming source/drain via 276 includes depositing at least one electrically conductive material (e.g., a metal bulk material) over the second dielectric layer that fills the source/drain via opening and performing a planarization process to remove any of the at least one electrically conductive material that is disposed over a top of the second dielectric layer. The planarization process may be performed until reaching and exposing ILD layer 274. Remainders of the electrically conductive material form metal plugs and, in some embodiments, metal liners of source/drain via 276. The electrically conductive material of source/drain contact 266 and/or source/drain via 276 may include tungsten, ruthenium, cobalt, molybdenum, copper, aluminum, titanium, tantalum, iridium, palladium, platinum, nickel, tin, gold, silver, other suitable metal, alloys thereof, or combinations thereof. In some embodiments, source/drain contact 266 and source/drain via 276 are formed by a dual damascene process (e.g., electrically conductive material of source/drain contact 266 and electrically conductive material of source/drain via 276 are deposited at the same time).

Processing may further include frontside BEOL processing to form metallization layers of a frontside multilayer interconnect (F-MLI) structure 278 over ILD layer 274. F-MLI structure 278 may electrically connect devices (e.g., transistors, resistors, capacitors, inductors, etc.), components of devices (e.g., gates and/or source/drains), devices within F-MLI structure 278, components of F-MLI structure 278, or combinations thereof, such that the devices and/or components thereof can operate as specified by design requirements. The metallization layers may route signals between the devices and/or the components thereof and/or distribute signals (e.g., clock signals, voltage signals, ground signals, other signals, or combinations thereof) to the devices and/or the components thereof. In some embodiments, a metallization layer/level includes at least one interconnect structure disposed in an insulation layer, such as a metal line and a via disposed in a dielectric layer (e.g., a CESL and an ILD layer), where the via connects the metal line to a metal line of an interconnect in a different metallization layer.

Forming the first metallization layer/level may include forming a third dielectric layer (e.g., a CESL and an ILD layer) over ILD layer 274, patterning the dielectric layer to forming openings therein (such as an opening therein that exposes source/drain via 276), and forming metal lines (e.g., electrically conductive material(s)) in the openings. Metal lines of the first metallization layer can collectively be referred to as a metal one (M1) layer and individually referred to as M1 metal lines. In some embodiments, the first metallization layer includes vias that physically and/or electrically connect local, device-level contacts (e.g., source/drain via 276) to metal lines. In such embodiments, the vias of the first metallization layer can collectively be referred to as a via zero (V0) layer (and individually referred to as V0 vias). In such embodiments, the V0 layer may be a bottommost via layer of F-MLI feature 278.

Frontside BEOL processing may continue with forming additional metallization layers (levels) of F-MLI structure 278 over the first metallization layer. For example, BEOL processing may include forming a second metallization layer (i.e., a metal two (M2) layer and a via one (V1) layer), a third metallization layer (i.e., a metal three (M3) layer and a via two (V2) layer), a fourth metallization layer (i.e., a metal four (M4) layer and a via three (V3) layer), a fifth metallization layer (i.e., a metal five (M5) layer and a via four (V4) layer), a sixth metallization layer (i.e., a metal six (M6) layer and a via five (V5) layer), a seventh metallization layer (i.e., a metal seven (M7) layer and a via six (V6) layer) to an X metallization layer (i.e., a metal X (MX) layer and a via Y (VY) layer, where X is a total number of patterned metal line layers of the MLI feature and Y is a total number of patterned via layers of the MLI feature) over the first metallization layer. Each of the metallization layers may include a patterned metal line layer and a patterned via layer configured to provide at least one BEOL interconnect structure disposed in an insulation layer. F-MLI structure 278 may have any number of metal layers, via layers, dielectric layers, or combinations thereof depending on design requirements.

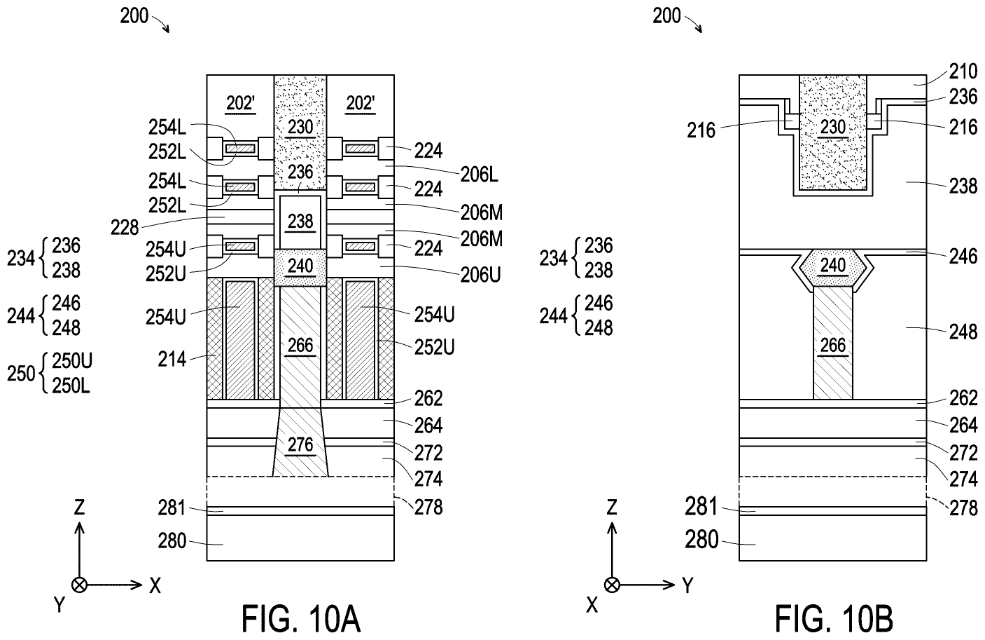

Referring to FIG. 2, FIG. 10A, and FIG. 10B, method 100 at block 130 includes exposing a backside of the dummy source/drain, such as dummy source/drain 230. In some embodiments, such as depicted, stacked device structure 200 is flipped over before exposing a backside of dummy source/drain 230, and processing involved with exposing the backside of dummy source/drain 230 and replacing dummy source/drain 230 with a lower source/drain (described hereafter) is performed on a backside of stacked device structure 200. In some embodiments, such processing includes attaching (bonding) a carrier substrate (wafer) 280 to a frontside of stacked device structure 200 by a bonding layer 281. For example, F-MLI structure 278, which forms the frontside of stacked device structure 200, may be bonded to carrier substrate 280 through bonding layer 281. In some embodiments, F-MLI structure 278 may be omitted, the second dielectric layer and/or source/drain via 276 may form the frontside of stacked device structure 200, and the second dielectric layer (e.g., ILD layer 274 thereof) and/or source/drain via 276 are bonded to carrier substrate 280 through bonding layer 281. In some embodiments, carrier substrate 280 is a bulk silicon substrate. In some embodiments, carrier substrate 280 includes a material that provides sufficient rigidity and/or mechanical support to stacked device structure 200 while undergoing backside processing. In some embodiments, bonding layer 281 is an oxide layer, such as a silicon oxide layer (e.g., an SiO₂ layer). In some embodiments, bonding layer 281 is another suitable material that facilitates bonding of carrier substrate 280 with the frontside of stacked device structure 200.

In some embodiments, a thinning process is performed on substrate 202 to expose the backside of dummy source/drain 230. The thinning process is a grinding process, a planarization process (e.g., CMP), an etching process, other suitable process, or combinations thereof. For example, a CMP is applied to a backside of stacked device structure 200, which is formed by substrate 202, and the CMP may reduce a thickness of substrate 202 and/or mesas 202′ along the z-direction. In the depicted embodiment, substrate 202 is completely removed by the thinning process, and mesas 202′ have a thickness t after the thinning process. In some embodiments, thickness t is about 5 nm to about 30 nm. In some embodiments, the thinning process stops upon reaching dummy source/drain 230. In some embodiments, the thinning process may reduce a thickness of dummy source/drain 230 along the z-direction to a desired thickness.

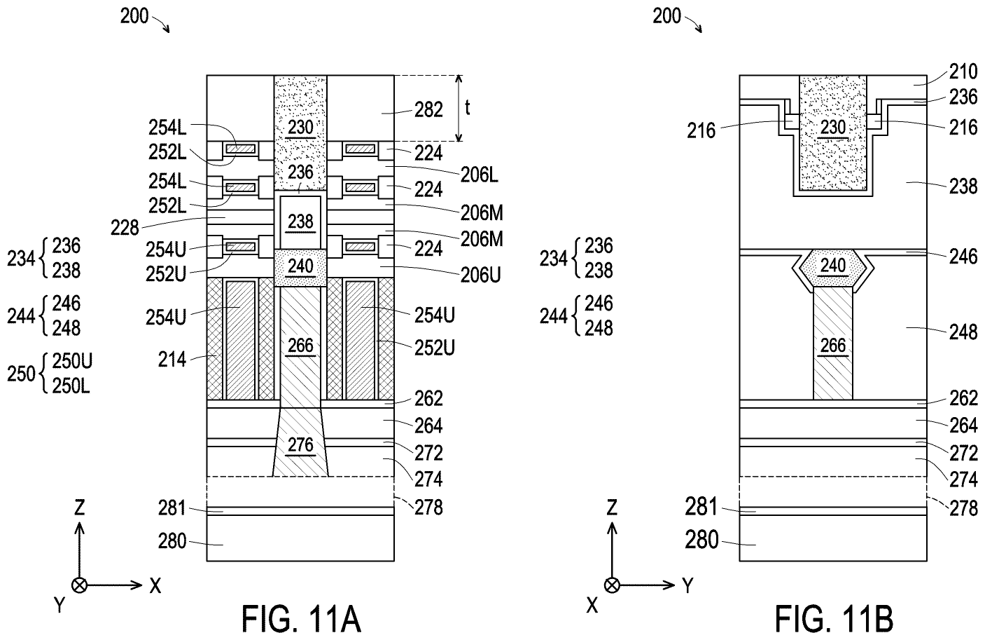

Referring to FIG. 11A and FIG. 11B, processing may include removing mesas 202′ (i.e., a de-mesa process) and/or any remainder of substrate 202. For example, a de-mesa process may replace mesas 202′ (and/or any remainder of substrate 202) with a backside insulation layer 282. Backside insulation layer 282 includes a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In the depicted embodiment, backside insulation layer 282 is an oxide layer, such as a silicon oxide layer (e.g., an SiO₂ layer). In some embodiments, backside insulation layer 282 is a low-k dielectric layer formed of a low-k dielectric material, such as those described herein. In some embodiments, backside insulation layer 282 has a multilayer structure, such as a dielectric layer over a dielectric liner.

The de-mesa process may include applying an etching process to the backside of stacked device structure 200 to remove mesas 202′. The etching process may selectively remove mesas 202′ with respect to dummy source/drain 230, gate stacks 250 (e.g., gate dielectrics 252L thereof), inner spacers 224, or combinations thereof. For example, the etching process etches mesas 202′ with no (or negligible) etching of dummy source/drain 230, gate stacks 250 (e.g., gate dielectrics 252L thereof), inner spacers 224, or combinations thereof. Because mesas 202′ may be selectively removed with respect to dummy source/drain 230, mesas 202′ may be removed without an etch mask and/or without performing a lithography process.

The de-mesa process may further include depositing a dielectric material over the backside of stacked device structure 200 after removing mesas 202′. In some embodiments, a planarization process (e.g., CMP) is performed on the dielectric material, and a remainder of the dielectric material forms backside insulation layer 282. The planarization process may remove dielectric material over the backside of dummy source/drain 230. In some embodiments, the planarization process is performed until reaching (exposing) dummy source/drain 230, and backside insulation layer 282 may have the same thickness as mesas 202′ before the de-mesa process, such as thickness t. In some embodiments, the planarization process may reduce a thickness of dummy source/drain 230 and/or backside insulation layer 282. In such embodiments, backside insulation layer 282 has a thickness less than thickness t.

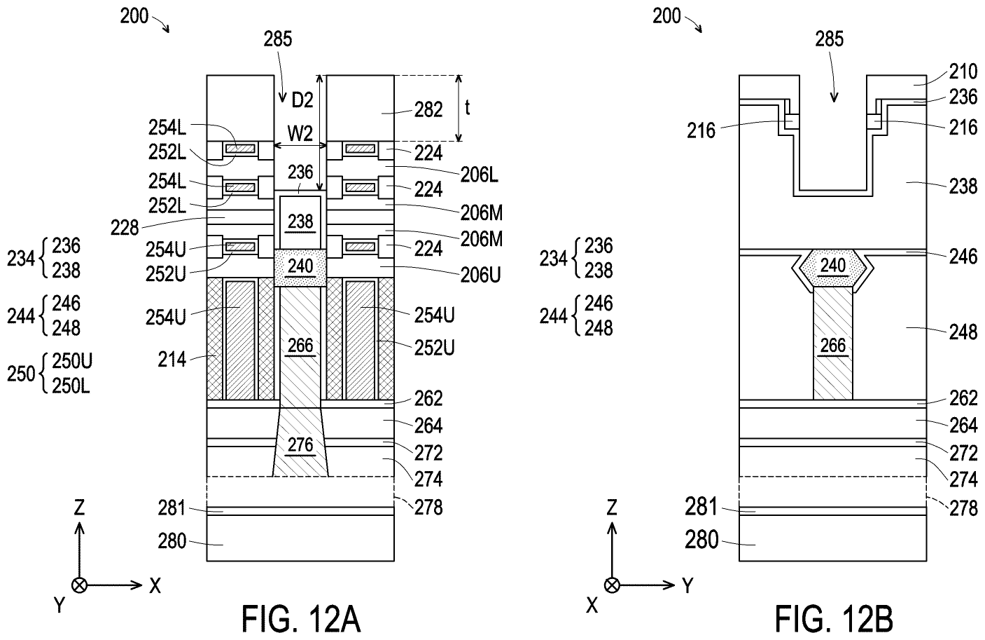

Referring to FIG. 2, FIG. 12A, and FIG. 12B, method 100 at block 130 includes removing the dummy source/drain to form a backside source/drain trench. For example, dummy source/drain 230 is removed to form a source/drain trench 285. In the depicted embodiment, source/drain trench 285 exposes dielectric layer 234 (i.e., the source/drain isolation structure) and sidewalls of semiconductor layers 206L (i.e., channel layers of the lower transistors). In FIG. 12A, source/drain trench 285 has a bottom formed by dielectric layer 234 (e.g., CESL 236 thereof) and sidewalls formed by backside insulation layer 282, inner spacers 224, and semiconductor layers 206L. In FIG. 12B, source/drain trench 285 has a bottom formed by dielectric layer 234 (e.g., CESL 236 thereof) and sidewalls formed by substrate isolation structure 210, fin spacers 216, and dielectric layer 234 (e.g., CESL 236 thereof).

Source/drain trench 285 has width W2 along the x-direction and a depth D2 along the z-direction. Depth D2 is between a surface of backside insulation layer 282 that forms a backside of stacked device structure 200 and a bottom of source/drain trench 285, and depth D2 is greater than width W2. An aspect ratio of source/drain trench 285 (AR_{L}) is given by a ratio of depth D2 to width W2. Aspect ratio AR_{L} is less than the aspect ratio of openings between dummy gates 212 (e.g., a ratio of depth D1 to width W1) after forming source/drain trench 220 (frontside source/drain trench). For example, aspect ratio AR_{L} is less than 10 (i.e., AR_{L}<10). In some embodiments, AR_{L} is less than 5 (i.e., AR_{L}≤5), such as about 1 to about 5. If aspect ratio AR_{L} is too high (e.g., >5), lower source/drain formation may suffer from similar issues that arise when performed in source/drain 220 before upper source/drain 240 (e.g., poor yield, poor dopant and/or constituent profile control, etc.). If aspect ratio AR_{L} is too low (e.g., <1), a subsequently formed lower source/drain may be too thin (and thus not provide sufficient strain) and/or a process window for lower source/drain may be less flexible. Providing a lower aspect ratio trench for lower source/drain formation facilitates better control of dopant and/or concentrations of dopants and/or constituents of a lower source/drain, such as described herein. In some embodiments, width W2 is the same as width W1. In some embodiments, width W2 is different than width W1. In some embodiments, depth D2 is the same as height h1. In some embodiments, depth D2 is different than height h1. In some embodiments, width W2 is less than about 20 nm. In some embodiments, depth D2 is about 40 nm to about 80 nm.

Source/drain trench 285 may be formed by applying an etching process to the backside of stacked device structure 200. The etching process may selectively remove dummy source/drain 230 with respect to backside insulation layer 282, dielectric layer 234 (e.g., CESL 236 thereof), inner spacers 224, semiconductor layers 206L, or combinations thereof. For example, the etching process etches dummy source/drain 230 with no (or negligible) etching of backside insulation layer 282, CESL 236, inner spacers 224, and semiconductor layers 206L. Because dummy source/drain 230 may be selectively removed with respect to backside insulation layer 282, dummy source/drain 230 may be removed without an etch mask, and dummy source/drain 230 may be removed without performing a lithography process. Further, because dummy source/drain 230 may be selectively removed with respect to backside insulation layer 282, inner spacers 224, and semiconductor layers 206L, source/drain trench 285 (i.e., a lower source/drain trench) is aligned with the source/drain region of stacked device structure 200 and/or upper source/drain 240 without performing a lithography process (i.e., source/drain trench 285 is self-aligned), thereby reducing time and/or complexity of source/drain fabrication. In some embodiments, the etching process implements an etchant that may etch a first semiconductor material (e.g., dummy source/drain 230 formed of Ge and/or Si₁₋ₓGeₓ) at a higher rate than dielectric materials (e.g., backside insulation layer 282, CESL 236, inner spacers 224, etc.) and a second semiconductor material (e.g., semiconductor layers 206L formed of Si). The etching process is a dry etch, a wet etch, other suitable etch, or combinations thereof.

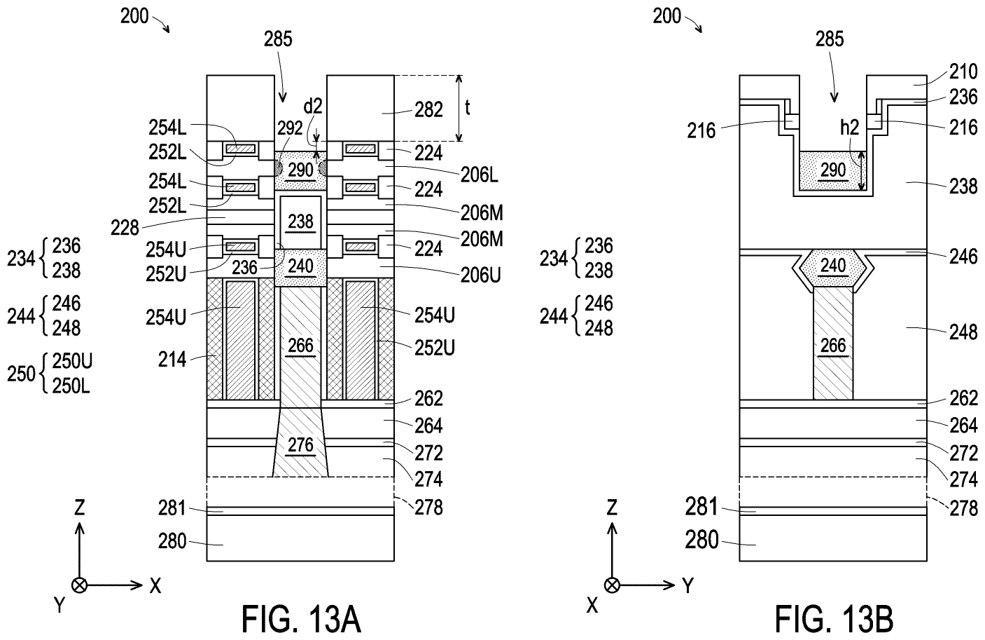

Referring to FIG. 2, FIG. 13A, and FIG. 13B, method 100 at block 135 includes forming a lower source/drain in the backside source/drain trench, such as lower source/drain 290 in source/drain trench 285. Lower source/drain 290 is formed over upper source/drain 240, lower source/drain 290 partially fills source/drain trench 285, and lower source/drain 290 is disposed between and adjacent to semiconductor layers 206L. In the depicted embodiment, lower source/drain 290 is also formed over dielectric layer 234 (i.e., the source/drain isolation structure). Lower source/drain 290 has a height h2 along the z-direction, and height h2 is less than depth D2. In some embodiments, height h2 is about 10 nm to about 50 nm. In some embodiments, height h2 is less than about 20 nm. In some embodiments, a thickness of lower source/drain 290 (e.g., given by height h2) is different than (e.g., less than) a thickness of upper source/drain 240 along the z-direction. In some embodiments, a thickness of lower source/drain 290 is the same as a thickness of upper source/drain 240. In some embodiments, such as depicted, a cross-sectional profile of lower source/drain 290 is different than a cross-sectional profile of upper source/drain 240 (see, e.g., FIG. 13B). For example, since lower source/drain 290 is formed after dielectric layer 234, lower source/drain 290 may be confined by dielectric layer 234 (e.g., CESL 236 thereof), such that lower source/drain 290 may not extend laterally over and/or beyond fin spacers 216. In such example, in the Y-Z plane, a width of upper source/drain 240 may be greater than a width of the lower source/drain 290. Further, in such example, in the Y-Z plane, a configuration/number of sidewall facets of upper source/drain 240 may be different than a configuration/number of sidewall facets of lower source/drain 290.

Since lower source/drain 290 is formed in source/drain trench 285 (i.e., in a backside source/drain trench after removal of substrate 202), instead of in source/drain trench 220 (i.e., in a frontside source/drain trench, a portion of which is formed in substrate 202), lower source/drain 290 is not formed in substrate 202, and lower source/drain 290 does not extend beyond gate stacks 250. Accordingly, when stacked device structure 200 is oriented frontside up, a bottom of lower source/drain 290 is above bottoms of gate stacks 250 (e.g., formed by gate dielectrics 252L thereof). A distance d2 along the z-direction may be between the bottom of lower source/drain 290 and the bottoms of gate stacks 250 (and/or a top of backside insulation layer 282). In some embodiments, distance d2 is zero, and lower source/drain 290, gate stacks 250 (e.g., gate dielectrics 252L thereof), and inner spacers 224 may form a common surface.

Lower source/drain 290 may be formed by an epitaxy process that epitaxially grows a semiconductor material from exposed semiconductor layers 206L that fills a bottom portion of source/drain trench 285. Because the aspect ratio of source/drain trench 285 is much less than the aspect ratio of source/drain trench 220, lower source/drain 290 may be epitaxially grown at a temperature that is lower than a temperature needed to epitaxially grow lower source/drain 290 in source/drain trench 220. For example, lower source/drain 290 may be formed by an epitaxial growth process that implements a temperature less than about 400° C., whereas an epitaxial growth process would implement a temperature of about 500° C. to about 700° C. to form lower source drain 290 in source/drain trench 220. The low-temperature epitaxial growth process may reduce dopant diffusion and/or constituent diffusion (e.g., from lower source/drain 290 to semiconductor layers 206L), which enables lower source/drain 290 to have higher dopant concentrations and/or higher constituent concentrations (e.g., germanium concentrations that are greater than about 60%) than if formed in source/drain trench 220. The higher dopant concentrations and/or the higher constituent concentrations may reduce source/drain contact resistance, which may enable thinner lower source/drains (e.g., height h2 of lower source/drain 290 may be about 10 nm to about 30 nm (e.g., about 20 nm)) and/or eliminate the need for additional doping processes (e.g., an additional implantation process) to increase the dopant concentration and/or the constituent concentration of lower source/drain 290.

The epitaxy process may use CVD deposition techniques (e.g., RPCVD, LPCVD, VPE, UHV-CVD, or combinations thereof), MBE, other suitable epitaxy process, or combinations thereof. The epitaxy process may use gaseous precursors and/or liquid precursors, which may interact with and/or adsorb on the composition of semiconductor layers 206L, but not interact with compositions of inner spacers 224, backside insulation layer 282, dielectric layer 234 (e.g., CESL 236 thereof), fin spacers 216, substrate isolation structure 210, or combinations thereof. In some embodiments, lower source/drain 290 is doped during deposition (i.e., in-situ), for example, by adding dopant to a source material of the epitaxy process. In some embodiments, lower source/drain 290 is doped after deposition thereof, for example, by an ion implantation process. In some embodiments, annealing processes are performed to activate dopants in lower source/drain 290. In some embodiments, lower source/drain 290 includes materials and/or dopants that achieve desired tensile stress and/or compressive stress in channel regions (e.g., semiconductor layers 206L) of the lower transistors.

In the depicted embodiment, the lower transistors of stacked device structure 200 are p-type transistors, and lower source/drain 290 is configured for p-type transistors. For example, lower source/drain 290 includes silicon germanium or germanium doped with boron, other p-type dopant, or combinations thereof. In such example, lower source/drain 290 may be an Si:Ge:B epitaxial source/drain. In some embodiments, the lower transistors of stacked device structure 200 are n-type transistors, and lower source/drain 290 is configured for n-type transistors. For example, lower source/drain 290 includes silicon doped with carbon, phosphorous, arsenic, other n-type dopant, or combinations thereof. In such example, lower source/drain 290 may be an Si:C epitaxial source/drain, an Si:P epitaxial source/drain, or an Si:C:P epitaxial source/drain. Lower source/drain 290 may have a multilayer structure. For example, lower source/drain 290 may include semiconductor layers having different compositions, and the different compositions may be achieved by configuring the semiconductor layers with different semiconductor materials, different dopants, different atomic percentages of constituents thereof, different dopant concentrations, or combinations thereof. In some embodiments, lower source/drain 290 may include a semiconductor material having a first dopant concentration of a dopant, and lower source/drain 290 may further include portions of the semiconductor material having a second dopant concentration of the dopant that is less than the first dopant concentration, which are depicted as semiconductor layers 292 adjacent to semiconductor layers 206L in FIG. 13A. In some embodiments, the semiconductor material is silicon germanium, the dopant is boron, the first dopant concentration of boron is less than about 5×10²⁰ atoms/cm³ (e.g., about 5×10¹⁹ atoms/cm³ to about 5×10²⁰ atoms/cm³), and the second dopant concentration of boron is greater than about 5×10²⁰ atoms/cm³. In some embodiments, the semiconductor material is silicon, the dopant is phosphorous, the first dopant concentration of phosphorous is less than about 1×10²¹ atoms/cm³ (e.g., about 1×10²⁰ atoms/cm³ to about 1×10²¹ atoms/cm³), and the second dopant concentration of phosphorous is greater than about 1×10²¹ atoms/cm³. In some embodiments, lower source/drain 290 may include a semiconductor material having a first concentration of a constituent, and lower source/drain 290 may further include portions of the semiconductor material (e.g., semiconductor layers 292) having a second concentration of the constituent that is less than the first concentration. In some embodiments, the semiconductor material is silicon germanium, the constituent is germanium, the first concentration of germanium is less than about 55% (e.g., about 20% to about 55%), and the second concentration of germanium is greater than about 55% (e.g., greater than about 60%). In some embodiments, since lower source/drain 290 is formed during backside processing, a dopant concentration and/or a constituent concentration of lower source/drain 290 may decrease from bottom to top when stacked device structure 200 is oriented frontside up. For example, a portion of lower source/drain 290 that interfaces with the source/drain isolation structure (e.g., CESL 236 thereof) and forms a top of lower source/drain 290 may have the lowest dopant concentration and/or the lowest constituent concentration, while a portion of lower source/drain 290 that will interface with a backside source/drain contact and form a bottom of lower source/drain 290 may have the highest dopant concentration and/or the highest constituent concentration. In such example, the dopant concentration and/or the constituent concentration may increase in a graded manner from top to bottom of lower source/drain 290.

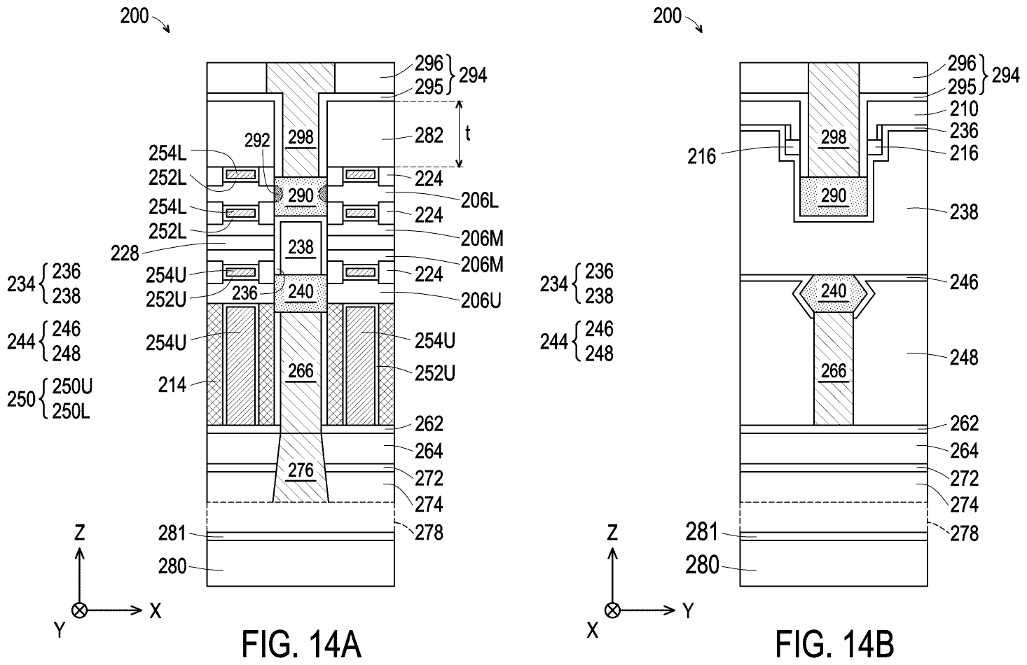

Referring to FIG. 14A and FIG. 14B, processing may further include forming a backside, lower source/drain interconnect to lower source/drain 290. Forming the backside lower source/drain interconnect may include forming a dielectric layer 294 (e.g., a CESL 295 and an ILD layer 296) over backside insulation layer 282 and/or substrate isolation structure 210, forming a source/drain contact opening in dielectric layer 294 that exposes lower source/drain 290, and forming a source/drain contact 298 in the source/drain contact opening. In some embodiments, a silicidation process is performed to form a lower silicide layer over lower source/drain 290 before forming source/drain contact 298. In some embodiments, forming source/drain contact 298 includes depositing at least one electrically conductive material (e.g., a metal bulk material) over dielectric layer 294 that fills the source/drain contact opening and performing a planarization process to remove any of the at least one electrically conductive material that is disposed over dielectric layer 294. The planarization process may be performed until reaching and exposing ILD layer 296. Remainders of the electrically conductive material form metal plugs and, in some embodiments, metal liners of source/drain contact 298. The electrically conductive material of source/drain contact 298 may include tungsten, ruthenium, cobalt, molybdenum, copper, aluminum, titanium, tantalum, iridium, palladium, platinum, nickel, tin, gold, silver, other suitable metal, alloys thereof, or combinations thereof.

Processing may further include backside BEOL processing to form metallization layers of a backside multilayer interconnect (B-MLI) structure over ILD layer 296. The B-MLI structure may electrically connect devices (e.g., transistors, resistors, capacitors, inductors, etc.), components of devices (e.g., gates and/or source/drains), devices within B-MLI structure, components of B-MLI structure, or combinations thereof, such that the devices and/or components thereof can operate as specified by design requirements. B-MLI structure may be similar to F-MLI structure 278. For example, BMLI-1 structure may include metallization layers that route signals between devices and/or components thereof and/or distribute signals (e.g., clock signals, voltage signals, ground signals, other signals, or combinations thereof) to devices and/or components thereof. Each of the metallization layers may include a patterned metal line layer and a patterned via layer configured to provide at least one BEOL interconnect structure disposed in an insulation layer. In some embodiments, a backside metallization layer/level may include at least one interconnect structure disposed in an insulation layer, such as a metal line and a via disposed in a dielectric layer (e.g., a CESL and an ILD layer), where the via connects the metal line to a metal line of an interconnect in a different metallization layer. In some embodiments, B-MLI structure may include a first metallization layer, which may be a device-level contact layer and/or a device-level via layer (collectively referred to as a backside via zero layer (BV0 level) and, in the depicted embodiment, may be provided by dielectric layer 294, backside insulation layer 282, and source/drain contact 298), a second metallization layer (i.e., a backside metal one (BM1) layer and a backside via one (BV1) layer), and a third metallization layer (i.e., a backside metal two (BM2) layer and a backside via two (BV2) layer). B-MLI structure may have any number of metal layers, via layers, dielectric layers, or combinations thereof.

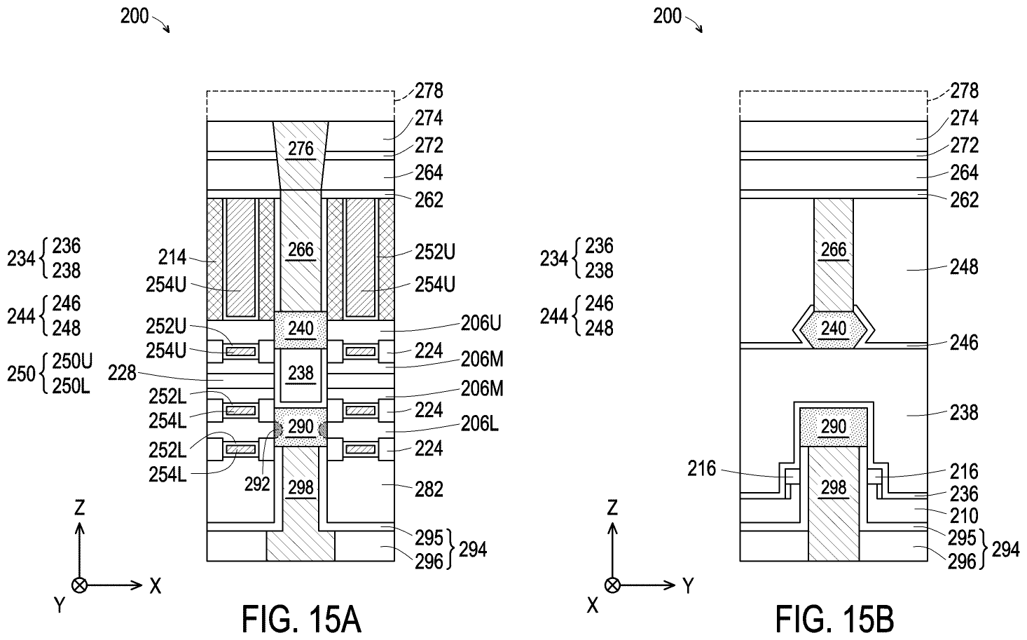

Referring to FIG. 15A and FIG. 15B, processing may further include flipping stacked device structure 200 over, such that stacked device structure 200 is re-oriented so that F-MLI structure 278 forms a top/frontside of thereof and dielectric layer 294 and source/drain contact 298 (or a B-MLI structure) form a backside thereof. Carrier substrate 280 and bonding layer 281 may be removed before or after flipping stacked device structure by a planarization process, an etching process, other suitable process, or combinations thereof.

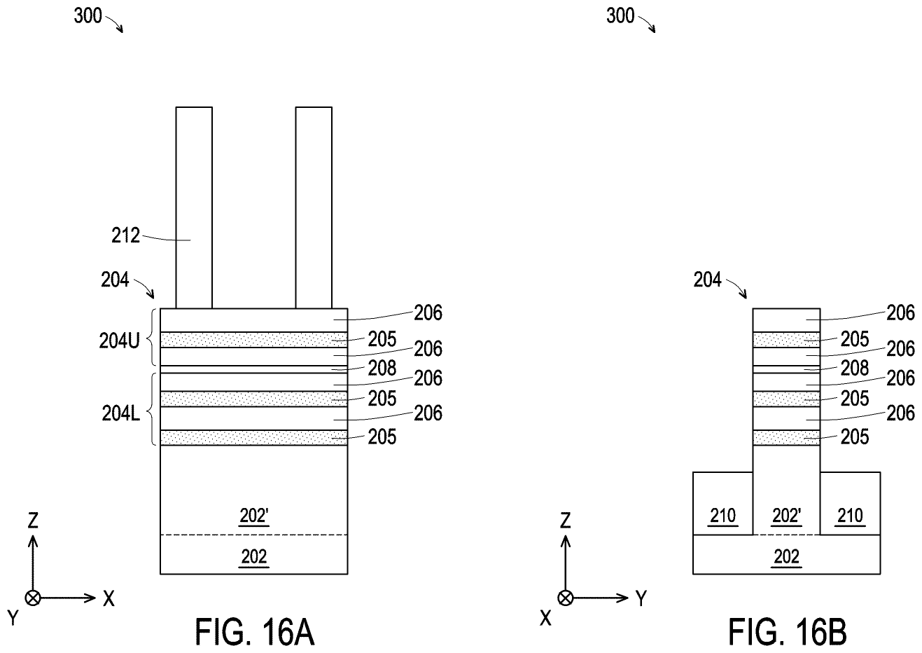

FIGS. 16A-28A and FIGS. 16B-28B are cross-sectional views of another stacked device structure, such as a stacked device structure 300, in portion or entirety, at various fabrication stages associated with method 100 of FIG. 2, according to various aspects of the present disclosure. FIGS. 16B-28B are taken through source/drain regions of stacked device structure 300 along B-B of FIGS. 16A-28A, respectively. Stacked device structure 300 is similar in many respects to stacked device structure 200 described above with reference to FIGS. 3A-15A and FIGS. 3B-15B. Similar features of stacked device structure 300 in FIGS. 16A-28A and FIGS. 16B-28B and stacked device structure 200 in FIGS. 3A-15A and FIGS. 3B-15B are thus identified by the same reference numerals for clarity and simplicity. FIGS. 16A-28A and FIGS. 16B-28B are discussed concurrently herein for ease of description and understanding. FIGS. 16A-28A and FIGS. 16B-28B have been simplified for the sake of clarity to better understand the inventive concepts of the present disclosure. Additional features may be added in stacked device structure 300, and some of the features described below may be replaced, modified, or eliminated in other embodiments of stacked device structure 300.

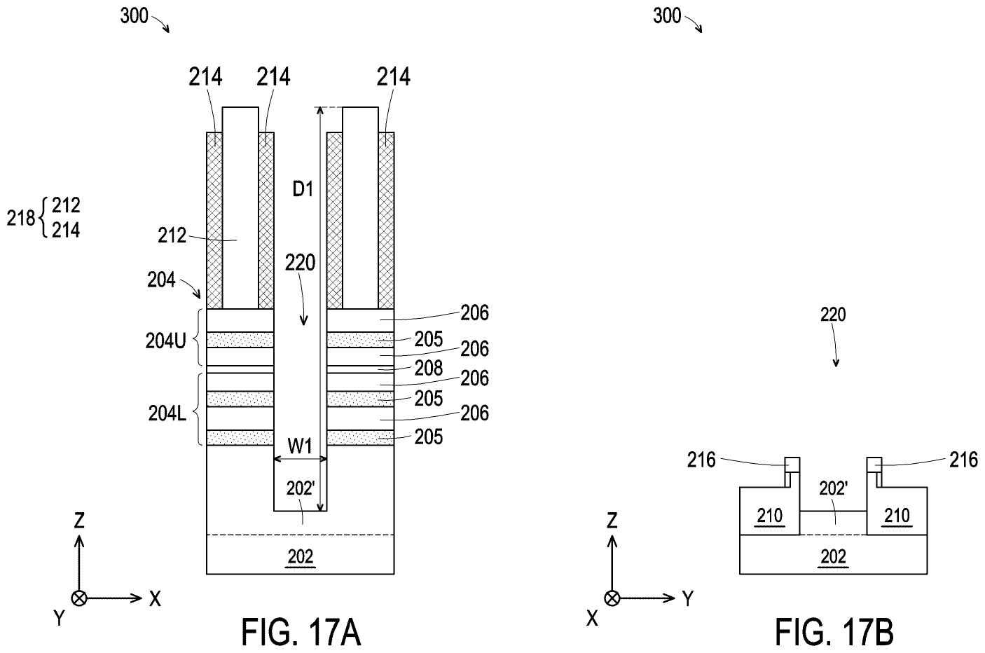

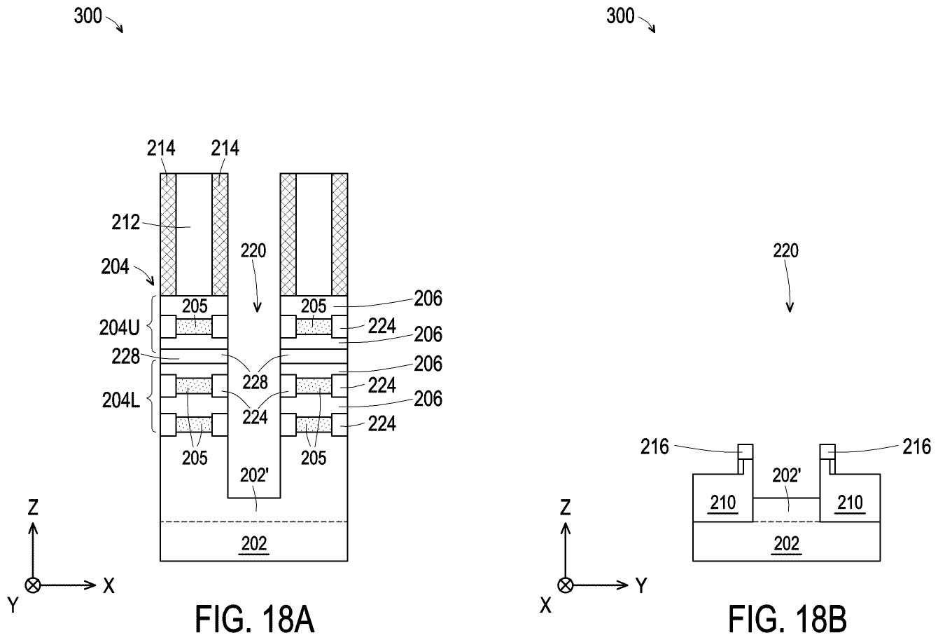

Referring to FIG. 2, FIG. 16A, and FIG. 16B, fabrication may include receiving and/or forming a device precursor at block 105 of method 100, such as described above with reference to FIG. 3A and FIG. 3B. The device precursor may include substrate 202, multilayer projection 204 (e.g., including mesa 202′, semiconductor layers 205, semiconductor layers 206, and intermediate layer 208), substrate isolation structure 210, and dummy gates 212. The device precursor may be processed to form source/drains of stacked device structure 300, such as described herein. Referring to FIG. 2, FIG. 17A, and FIG. 17B, source/drain trench 220 is formed in the source/drain region of multilayer projection 204 at block 110 of method 100, such as described above with reference to FIG. 4A and FIG. 4B. Referring to FIG. 18A and FIG. 18B, processing of stacked device structure 300 may include forming inner spacers 224 under gate spacers 214 and adjacent to semiconductor layers 205, and replacing intermediate layer 208 with insulation layer 228, such as described above with reference to FIG. 5A and FIG. 5B.

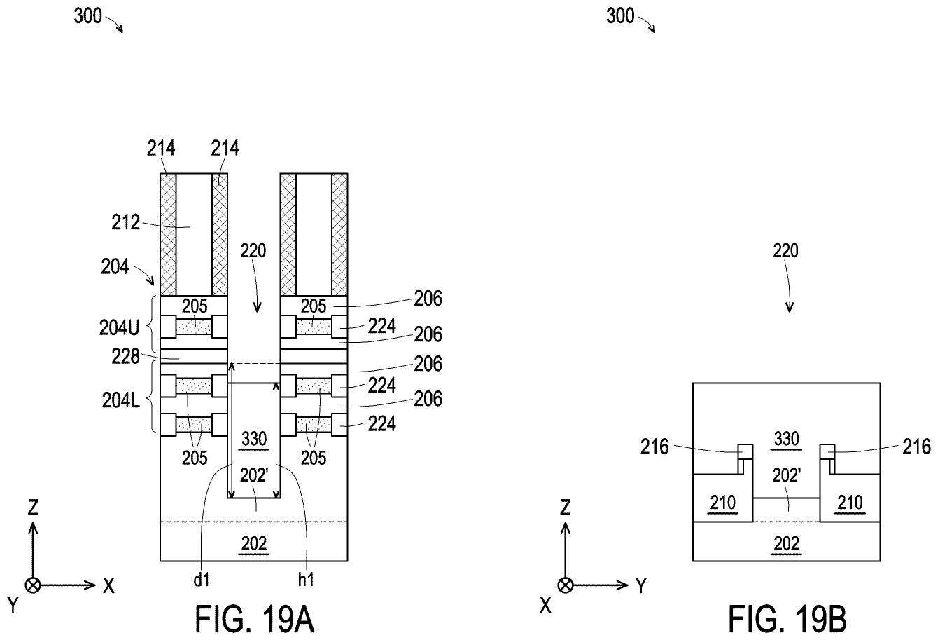

Referring to FIG. 2, FIG. 19A, and FIG. 19B, instead of forming dummy source/drain 220 (FIG. 6A and FIG. 6B), fabrication of stacked device structure 300 includes forming a dummy source/drain 330 in source/drain trench 220 (i.e., the frontside source/drain trench) at block 115 of method 100. Dummy source/drain 330 is formed in and partially fills source/drain trench 220, dummy source/drain 330 has height h1, and dummy source/drain 330 is below insulation layer 228. Height h1 is less than depth D1. In contrast to dummy source/drain 220 (see, e.g., FIG. 6B), dummy source/drain 330 is not confined to source/drain trench 220. For example, referring to FIG. 19B, dummy source/drain 330 extends laterally over and/or beyond fin spacers 216, and dummy source/drain 330 is disposed on/over substrate isolation structure 210. Dummy source/drain 330 is thus inside and outside of source/drain trench 220.

A composition of dummy source/drain 230 is different than a composition of mesa 202′, a composition of semiconductor layers 205, a composition of semiconductor layers 206, a composition of inner spacers 224, a composition of a subsequently formed backside insulation layer (e.g., backside insulation layer 282), a composition of a subsequently formed source/drain isolation structure (e.g., CESL 236 thereof), or combinations thereof to facilitate selective etching/removal therebetween. Dummy source/drain 230 includes a dielectric material, instead of a semiconductor material like dummy source/drain 220. The dielectric material is different than the dielectric materials of inner spacers 224, fin spacers 216, substrate isolation structure 210, backside insulation layer 282, the source/drain isolation structure (e.g., CESL 236 thereof), or combinations thereof. In some embodiments, dummy source/drain 330 is formed of a dielectric material that includes silicon and oxygen, carbon, nitrogen, or combinations thereof. For example, dummy source/drain 330 may be formed of silicon oxide (e.g., SiO₂), silicon oxycarbide (e.g., SiOC), silicon nitride (e.g., SiN and/or Si₃N₄), silicon oxycarbonitride (e.g., SiOCN), or combinations thereof. In some embodiments, dummy source/drain 330 is formed of a dielectric material that includes boron and oxygen, carbon, nitrogen, or combinations thereof. For example, dummy source/drain 330 may be formed of boron nitride (e.g., BN). In some embodiments, dummy source/drain 330 is formed of a dielectric material that includes metal and oxygen, carbon, nitrogen, or combinations thereof. For example, dummy source/drain 330 may be formed of aluminum nitride (e.g., AlN) and/or titanium oxide (e.g., TiO₂). In some embodiments, substrate isolation structure 210 and backside insulation layer 282 may be formed of silicon oxide, inner spacers 224 may be formed of silicon oxycarbonitride, CESL 236 is formed of silicon nitride, and dummy source/drain 330 may be formed of silicon oxycarbide, boron nitride, metal oxide, metal nitride, or combinations thereof. In some embodiments, dummy source/drain 330 may have a concentration of carbon that is different than a concentration of carbon of inner spacers 224, fin spacers 216, substrate isolation structure 210, backside insulation layer 282, or combinations thereof. For example, inner spacers 224 may have a concentration of carbon that is less than about 6 atomic percent (at %), and dummy source/drain 330 may have a carbon concentration that is greater than about 6 at %. In some embodiments, dummy source/drain 330 is formed of a dielectric material having a dielectric constant that is less than a dielectric constant of ILD layers and/or CESLs described herein (e.g., ILD layer 248 and/or CESL 246, in which upper source/drain 240 is disposed) and a dielectric constant of backside insulation layer 282, which may improve isolation of subsequently formed lower source/drain 290 and thereby improve device performance. For example, dummy source/drain 330 include boron and oxygen, carbon, nitrogen, or combinations thereof (e.g., boron nitride), while the ILD layers, the CESLs, backside insulation layer 282, or combinations thereof include silicon and oxygen, carbon, nitrogen, or combinations thereof.

Dummy source/drain 330 is formed by depositing a dielectric material over stacked device structure 300 that fills at least a lower portion of source/drain trench 220, such as a portion thereof that corresponds with a lower device level of stacked device structure 300 (e.g., below insulation layer 228). The dielectric material may be formed by a blanket deposition process, a spin-on deposition process, CVD, other deposition process, or combinations thereof. The dielectric material may be deposited inside and outside of source/drain recess 220 (e.g., by a non-selective deposition process). Forming dummy source/drain 330 may also include etching back the dielectric material. In some embodiments, the etching back removes dielectric material that forms in an upper portion of source/drain trench 220, such as a portion thereof that corresponds with an upper device level of stacked device structure 300 (e.g., above insulation layer 228). In some embodiments, a height of the dielectric material after deposition is greater than height h1, and the etching back may reduce the height of the dielectric material to a height that is less than distance d1. In some embodiments, the etching back reduces the height of the dielectric material to height h1. The etching back may selectively remove/etch the dielectric material with negligible removal/etching of semiconductor layers 206, dummy gates 212, gate spacers 214, inner spacers 224, insulation layer 228, or combinations thereof. The etching back is a dry etch, a wet etch, other suitable etch, or combinations thereof.

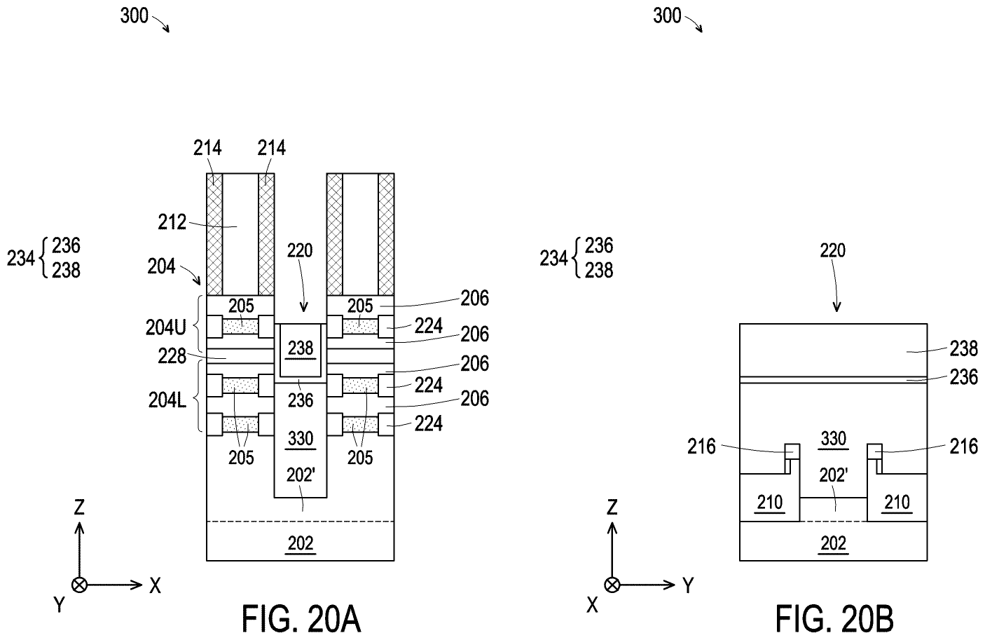

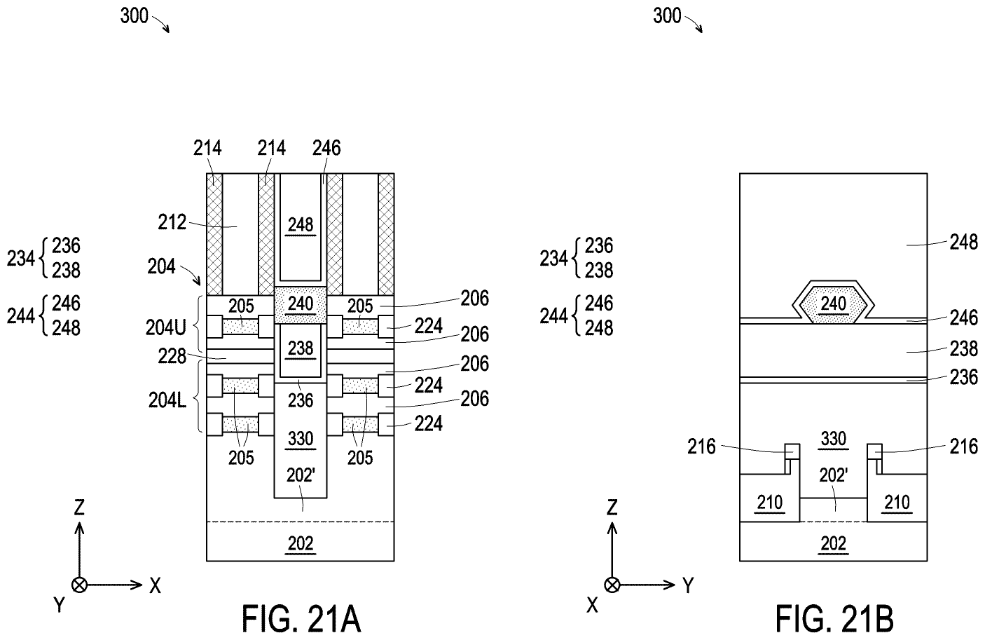

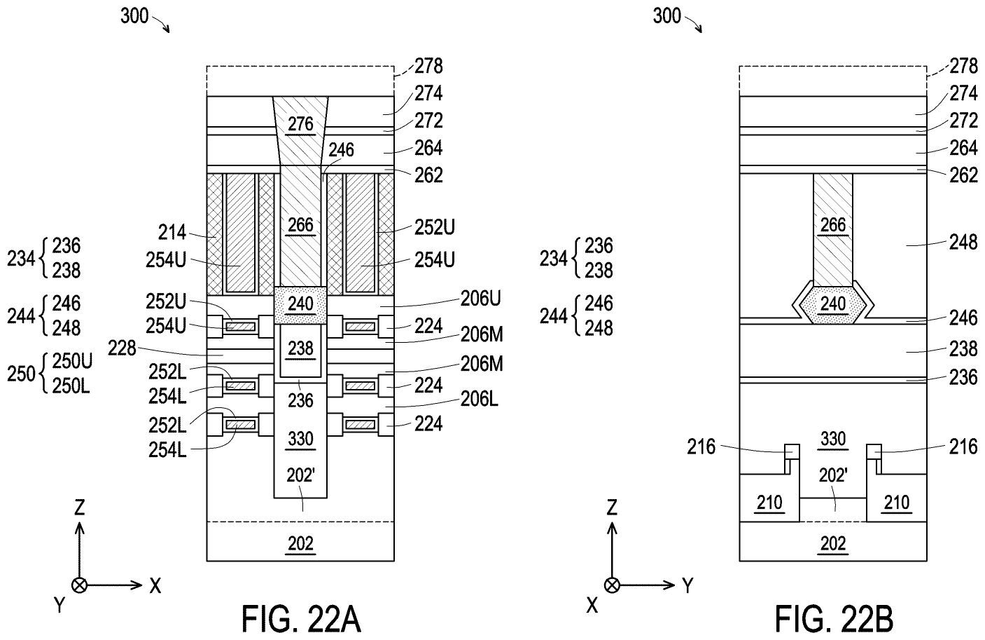

Referring to FIG. 2, FIG. 20A, and FIG. 20B, source/drain isolation structure (e.g., dielectric layer 234) is formed over dummy source/drain 330 in source/drain trench 220 at block 120 of method 100, such as described above with reference to FIG. 7A and FIG. 7B. In stacked device structure 300, since dummy source/drain 330 is formed outside source/drain trench 220, dummy source/drain 330 is between dielectric layer 234 and substrate isolation structure 210 and between dielectric layer 234 and fin spacers 216. Further, in FIG. 20B, dielectric layer 234 is disposed over a top, but not sidewalls of dummy source/drain 330, and dielectric layer 234 may not wrap dummy source/drain 330. Referring to FIG. 2, FIG. 21A, and FIG. 21B, upper source/drain 240 is formed over dummy source/drain 330 at block 125 of method 100, such as described above with reference to FIG. 8A and FIG. 8B. In the depicted embodiment, upper source/drain 240 is further formed over the source/drain isolation structure (e.g., dielectric layer 234). Processing may further include forming dielectric layer 244 over upper source/drain 240 and/or dielectric layer 234. Referring to FIG. 22A and FIG. 22B, processing may further include performing a gate replacement process (e.g., replacing dummy gates 212 (and semiconductor layers 205) with gate stacks 250), performing a channel release process (e.g., providing semiconductor layers 206U, semiconductor layers 206M, and semiconductor layers 206L), forming an upper source/drain interconnect to upper source/drain 240 (e.g., source/drain contact 266 and source/drain via 276, which may be disposed in dielectric layer 244, CESL 262, ILD layer 264, CESL 272, and ILD layer 274), and performing frontside BEOL processing (e.g., to form F-MLI structure 278), such as described above with reference to FIG. 9A and FIG. 9B.

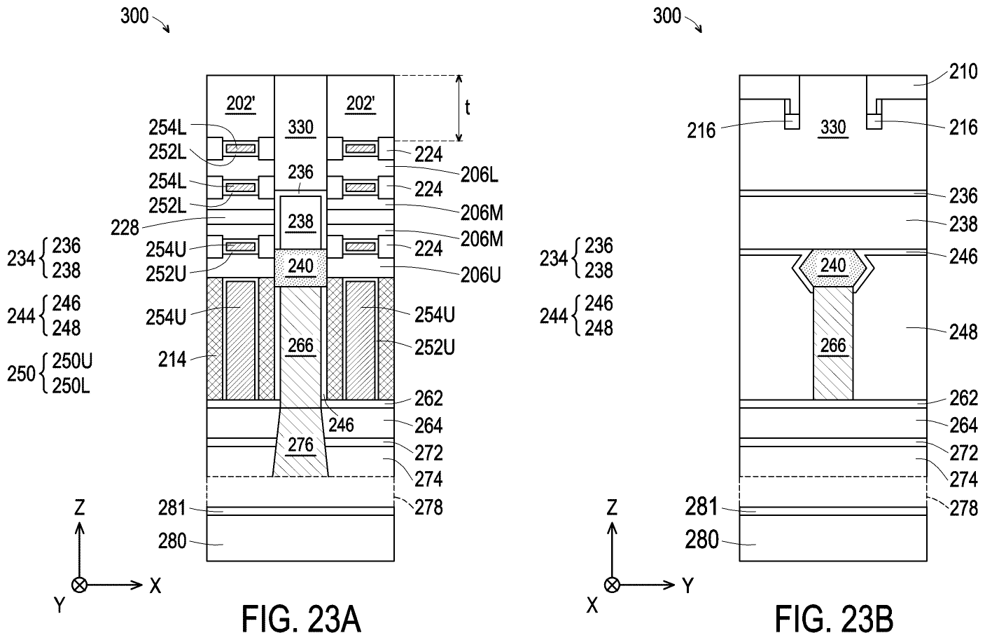

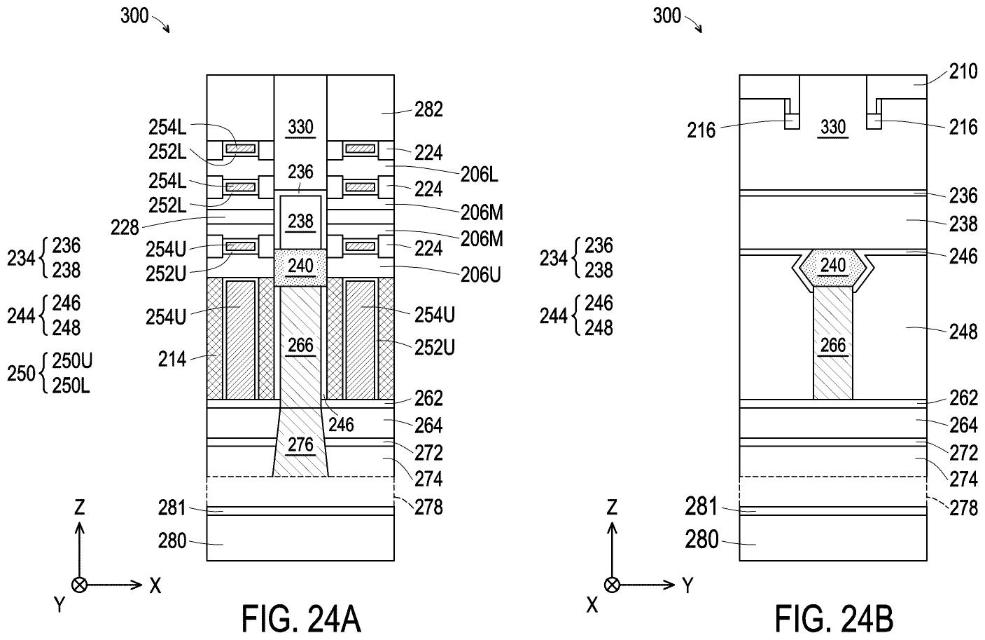

Referring to FIG. 2, FIG. 23A, and FIG. 23B, a backside of dummy source/drain 330 is exposed at block 130 of method 100, such as described above with reference to FIG. 10A and FIG. 10B. For example, processing may include attaching a frontside of stacked device structure 300 to carrier substrate 280 via bonding layer 281, flipping over stacked device structure 300 so that a bottom, backside thereof is oriented up, and performing a thinning process on substrate 202 to expose the backside of dummy source/drain 330. Referring to FIG. 24A and FIG. 24B, processing may further include performing a de-mesa process to replace mesas 202′ with backside insulation layer 282, such as described above with reference to FIG. 11A and FIG. 11B. In the depicted embodiment, a composition of backside insulation layer 282 is different than a composition of dummy source/drain 330 to enable selective etching/removal therebetween. For example, backside insulation layer 282 is formed of a dielectric material that is different than the dielectric material of dummy source/drain 330. The de-mesa process may include applying an etching process to the backside of stacked device structure 300 that removes mesas 202′ (which may expose inner spacers 224 and/or gate stacks 250 (e.g., gate dielectrics 252L thereof)), depositing a dielectric material over the backside of stacked device structure 300 after removing mesas 202′, and performing a planarization process. In the depicted embodiment, the etching process may selectively remove mesas 202′ with respect to dummy source/drain 330, gate stacks 250, inner spacers 224, or combinations thereof. For example, the etching process etches mesas 202′ with no (or negligible) etching of dummy source/drain 330, gate stacks 250 (e.g., gate dielectrics 252L thereof), inner spacers 224, or combinations thereof. Because mesas 202′ may be selectively removed with respect to dummy source/drain 330, mesas 202′ may be removed without an etch mask and/or without performing a lithography process.

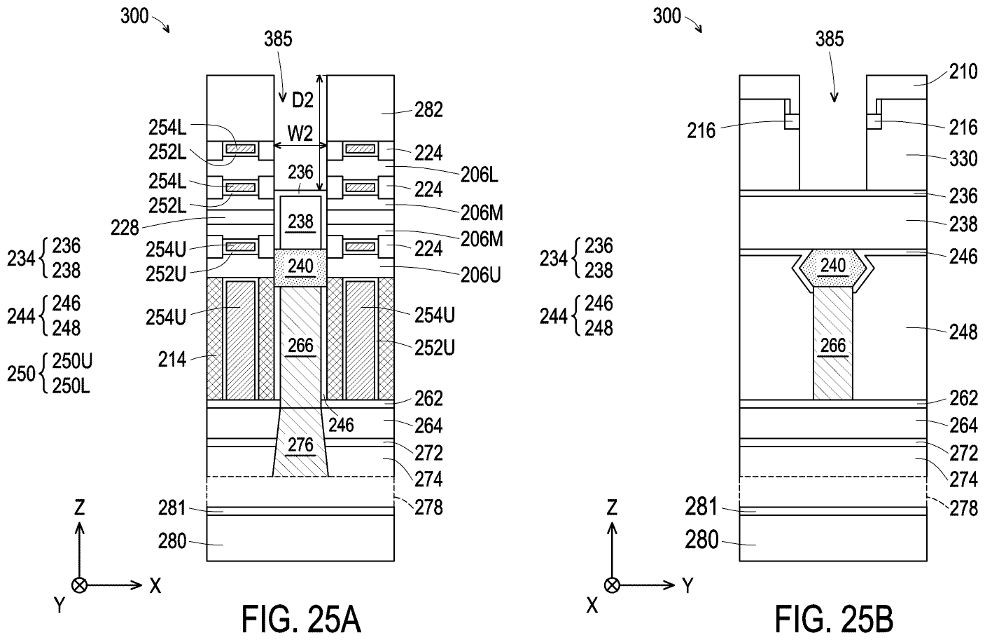

Referring to FIG. 2, FIG. 25A, and FIG. 25B, dummy source/drain 330 is removed to form a backside source/drain trench, such as a source/drain trench 385, at block 135 of method 100, such as described with reference to FIG. 12A and FIG. 12B. In the depicted embodiment, source/drain trench 385 exposes dielectric layer 234 (i.e., the source/drain isolation structure) and sidewalls of semiconductor layers 206L (i.e., channel layers of the lower transistors). In FIG. 25A, source/drain trench 385 has a bottom formed by dielectric layer 234 (e.g., CESL 236 thereof) and sidewalls formed by backside insulation layer 282, inner spacers 224, and semiconductor layers 206L. Since dummy source/drain 330 is formed outside of source/drain trench 220, a portion of dummy source/drain 330 remains in stacked device structure 300 after forming the backside source/drain trench. For example, dummy source/drain 330 may remain between substrate isolation structure 210 and dielectric layer 234 (e.g., CESL 236 thereof) and form sidewalls of source/drain trench 385. In FIG. 25B, in contrast to source/drain trench 285, source/drain trench 385 has a bottom formed by dielectric layer 234 and sidewalls formed by substrate isolation structure 210, fin spacers 216, and dummy source/drain 330.

Source/drain trench 385 may be formed by applying an etching process to the backside of stacked device structure 300. The etching process may selectively remove dummy source/drain 330 with respect to backside insulation layer 282, dielectric layer 234 (e.g., CESL 236 thereof), inner spacers 224, semiconductor layers 206L, or combinations thereof. For example, the etching process etches dummy source/drain 330 with no (or negligible) etching of backside insulation layer 282, CESL 236, inner spacers 224, and semiconductor layers 206L. Because dummy source/drain 330 may be selectively removed with respect to backside insulation layer 282, dummy source/drain 330 may be removed without an etch mask and/or without performing a lithography process. Further, because dummy source/drain 330 may be selectively removed with respect to backside insulation layer 282, inner spacers 224, and semiconductor layers 206L, source/drain trench 385 (i.e., a lower source/drain trench) is aligned with the source/drain region of stacked device structure 300 and/or upper source/drain 240 without performing a lithography process (i.e., source/drain trench 385 is self-aligned), thereby reducing time and/or complexity of source/drain fabrication. In some embodiments, the etching process implements an etchant that may etch a first dielectric material (e.g., dummy source/drain 330) at a higher rate than a second dielectric material (e.g., backside insulation layer 282), a third dielectric material (e.g., inner spacers 224), a fourth dielectric material (e.g., CESL 236), a fifth dielectric material (e.g., substrate isolation structure 210), a sixth dielectric material (e.g., fin spacers 216), and semiconductor materials (e.g., semiconductor layers 206L). One or more of the second dielectric material, the third dielectric material, the fourth dielectric material, the fifth dielectric material, and the sixth dielectric material may be the same dielectric material. The etching process is a dry etch, a wet etch, other suitable etch, or combinations thereof.

Source/drain trench 385 has width W2 and depth D2, and source/drain trench 385 has aspect ratio AR_{L}, which is less than the aspect ratio of openings between dummy gates 212 (e.g., a ratio of depth D1 to width W1) after forming source/drain trench 220 (frontside source/drain trench). In the depicted embodiment, in FIG. 25B, source/drain trench 385 has substantially vertical sidewalls. In such embodiments, the etching process may be an anisotropic etch that is configured to remove material in substantially one direction, such as a vertical direction (e.g., z-direction) with minimal (to no) removal of material in a horizonal direction (e.g., x-direction and/or y-direction). In some embodiments, the etching process may remove material (e.g., portions of dummy source/drain 330) along the vertical direction and the horizontal direction (i.e., the etching process may laterally etch dummy source/drain 330). In such embodiments, source/drain trench 385 may extend laterally over/under fin spacers 216 and/or substrate isolation structure 210, and source/drain trench 385 may have tapered sidewalls. For example, a width of source/drain trench 385 may decrease from top to bottom. The present disclosure contemplates various profiles of source/drain trench 385 depending on the etching process.

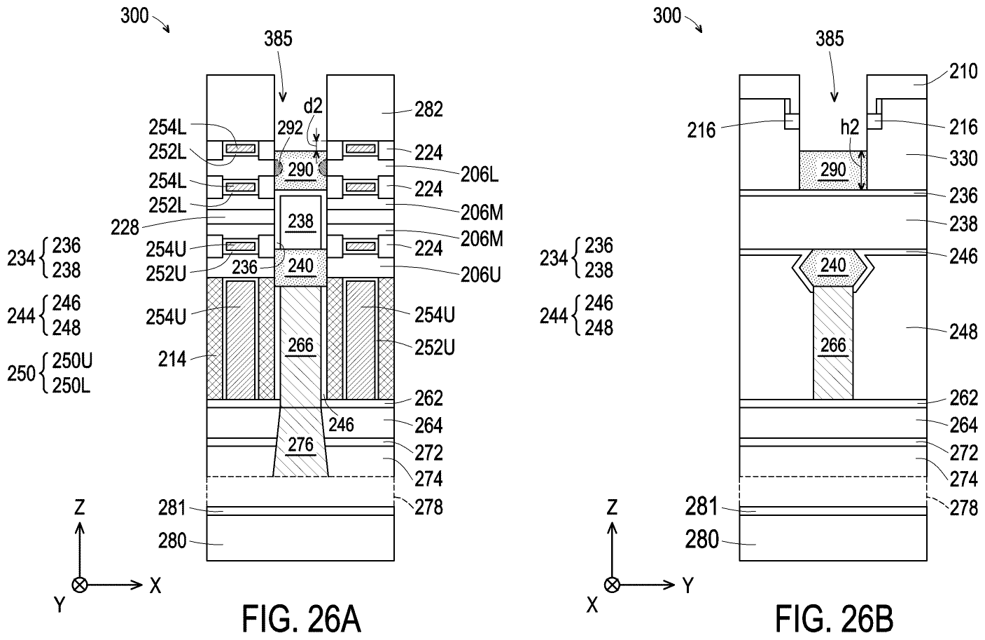

Referring to FIG. 2, FIG. 26A, and FIG. 26B, a lower source/drain, such as lower source/drain 290, is formed in the backside source/drain trench, such as in source/drain trench 385, at block 140 of method 100, such as described above with reference to FIG. 13A and FIG. 13B. Lower source/drain 290 is formed over upper source/drain 240, lower source/drain 290 partially fills source/drain trench 385, and lower source/drain 290 is disposed between and adjacent to semiconductor layers 206L. In the depicted embodiment, lower source/drain 290 is formed over dielectric layer 234 (i.e., the source/drain isolation structure), and lower source/drain 290 may also have height h2, which is less than depth D2, in source/drain trench 385. Further, since lower source/drain 290 is formed in source/drain trench 385 and after removal of substrate 202, distance d2 may be between the bottom of lower source/drain 290 and the bottoms of gate stacks 250 (i.e., lower source/drain 290 does not extend beyond the bottoms of gate stacks 250), such as described above.

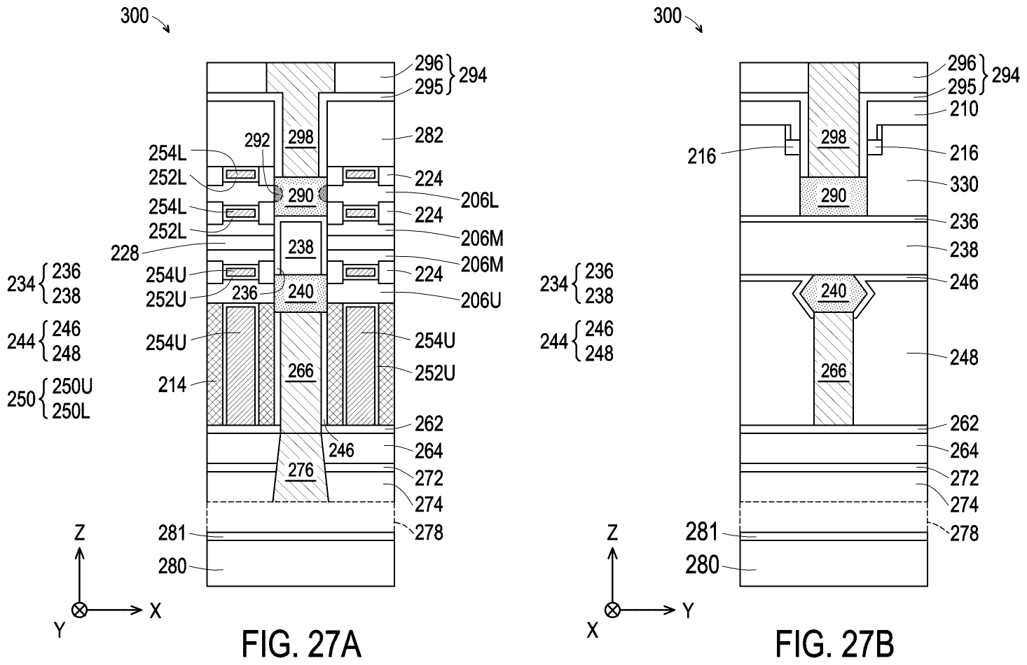

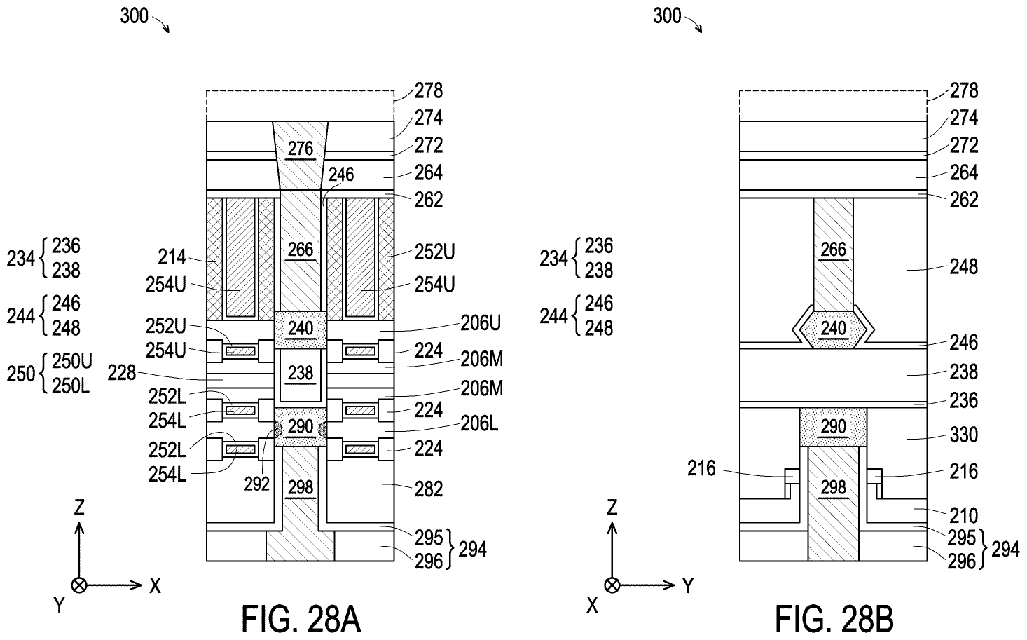

Referring to FIG. 27A and FIG. 27B, processing may further include forming a lower source/drain interconnect, such as source/drain contact 298, to lower source/drain 290, such as described above with reference to FIG. 14A and FIG. 14B. Source/drain contact 298 may be formed in backside insulation layer 282 and/or other insulation layers (e.g., dielectric layer 294, which may include CESL 295 and ILD layer 296). Processing may further include backside BEOL processing to form a B-MLI structure over dielectric layer 294. Referring to FIG. 28A and FIG. 28B, processing may further include flipping over stacked device structure 300, such that F-MLI structure 278 forms a top/frontside thereof and dielectric layer 294 and source/drain contact 298 form a bottom/backside thereof, and removing carrier substrate 280 and/or bonding layer 281, such as described above with reference to FIG. 15A and FIG. 15B.

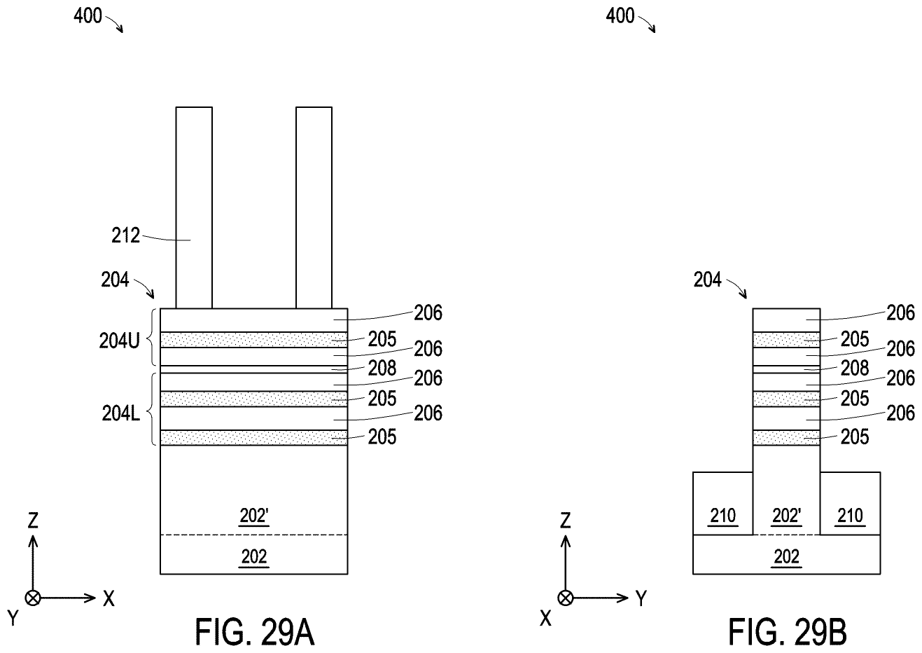

FIGS. 29A-40A and FIGS. 29B-40B are cross-sectional views of another stacked device structure, such as a stacked device structure 400, in portion or entirety, at various fabrication stages associated with method 100 of FIG. 2, according to various aspects of the present disclosure. FIGS. 29B-40B are taken through source/drain regions of stacked device structure 400 along B-B of FIGS. 29A-40A, respectively. Stacked device structure 400 is similar in many respects to stacked device structure 300 described above with reference to FIGS. 16A-28A and FIGS. 16B-28B. Similar features of stacked device structure 400 in FIGS. 29A-40A and FIGS. 29B-40B and stacked device structure 300 in FIGS. 16A-28A and FIGS. 16B-28B are thus identified by the same reference numerals for clarity and simplicity. FIGS. 29A-40A and FIGS. 29B-40B are discussed concurrently herein for ease of description and understanding. FIGS. 29A-40A and FIGS. 29B-40B have been simplified for the sake of clarity to better understand the inventive concepts of the present disclosure. Additional features may be added in stacked device structure 400, and some of the features described below may be replaced, modified, or eliminated in other embodiments of stacked device structure 400.

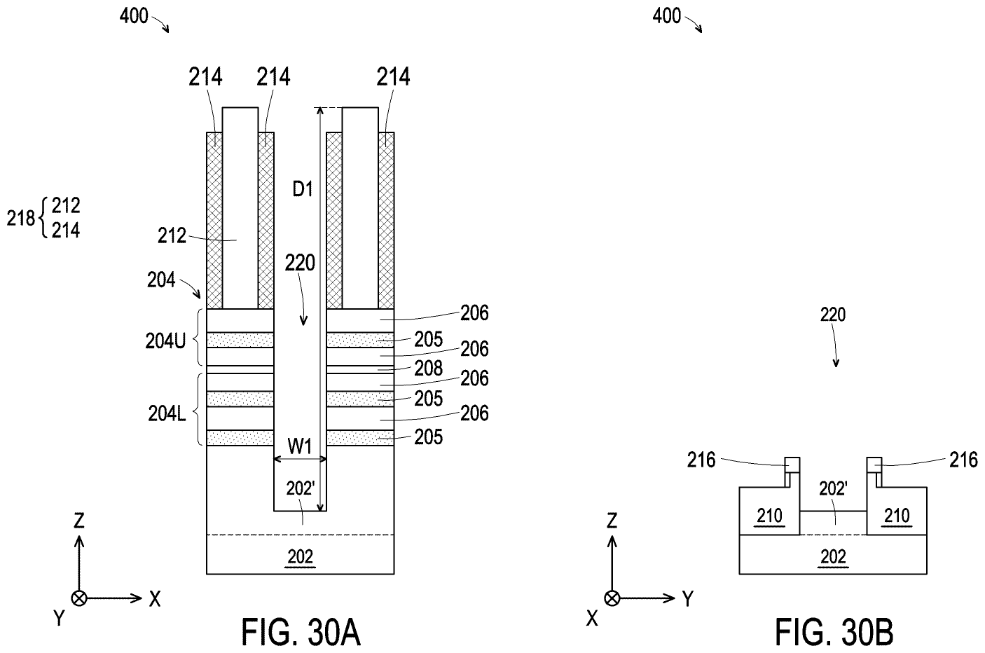

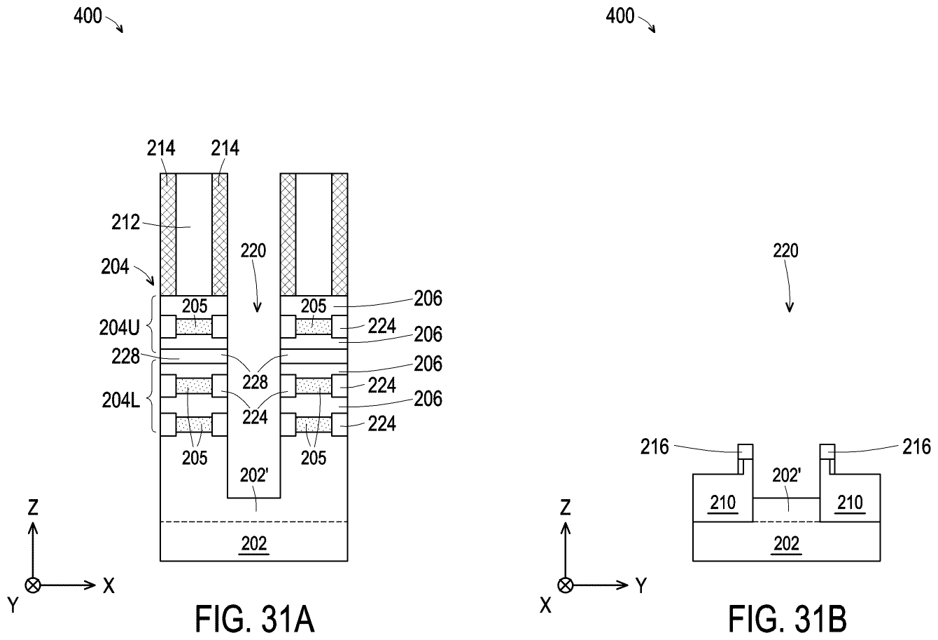

Referring to FIG. 2, FIG. 29A, and FIG. 29B, fabrication may include receiving and/or forming a device precursor at block 105 of method 100, such as described above with reference to FIG. 16A and FIG. 16B. The device precursor may include substrate 202, multilayer projection 204 (e.g., including mesa 202′, semiconductor layers 205, semiconductor layers 206, and intermediate layer 208), substrate isolation structure 210, and dummy gates 212. The device precursor may be processed to form source/drains of stacked device structure 400. Referring to FIG. 2, FIG. 30A, and FIG. 30B, source/drain trench 220 is formed in the source/drain region of multilayer projection 204 at block 110 of method 100, such as described above with reference to FIG. 17A and FIG. 17B. Referring to FIG. 31A and FIG. 31B, processing may include forming inner spacers 224 and replacing intermediate layer 208 with insulation layer 228, such as described above with reference to FIG. 18A and FIG. 18B.

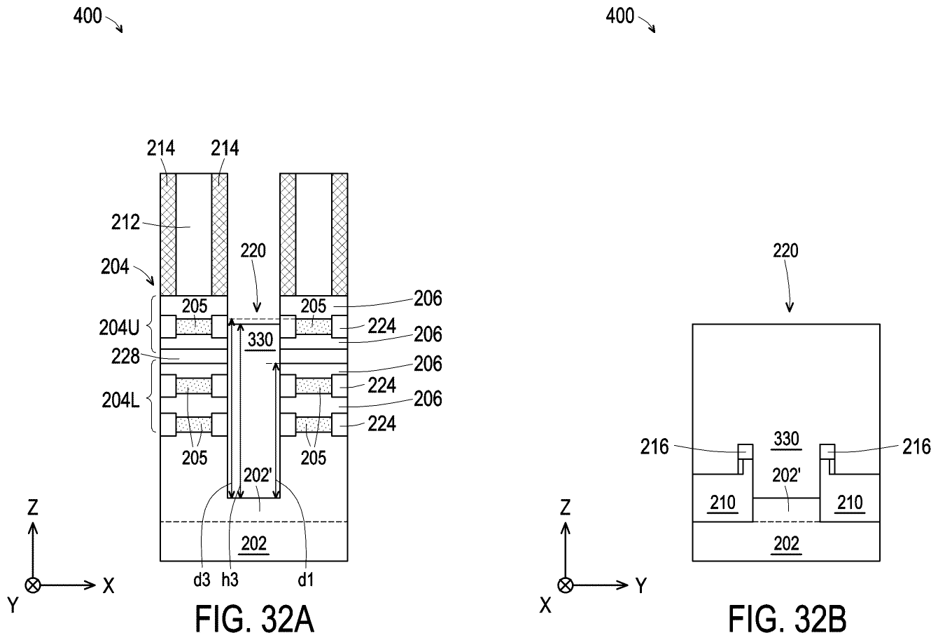

Referring to FIG. 2, FIG. 32A, and FIG. 32B, dummy source/drain 330 is formed in source/drain trench 220 (i.e., the frontside source/drain trench) at block 115 of method 100, such as described above with reference to FIG. 19A and FIG. 19B. In stacked device structure 400, a height of dummy source/drain 330 is increased to facilitate formation of lower source/drain 290 and provide a source/drain isolation structure. For example, in FIG. 32A and FIG. 32B, dummy source/drain 330 has a height h3 that is less than depth D1 but greater than height h1 of dummy source/drain 330 in stacked device structure 300 (see, e.g., FIG. 19A and FIG. 19B). Height h3 is greater than distance d1 and less than or equal to a distance d3, which is a distance between a bottommost active layer (e.g., a channel layer) of upper semiconductor stack 204U and a bottom of source/drain trench 220. In other words, dummy source/drain 230 is below semiconductor layers 206 of upper semiconductor stack 204U that will become channel layers. In the depicted embodiment, dummy source/drain 330 is below top semiconductor layer of upper semiconductor stack 204U (which will provide channel layers of upper transistors) and extends beyond bottom semiconductor layer of upper semiconductor stack 204U (which will provide dummy channel layers of upper transistors). In some embodiments, height h3 is less than about 120 nm. In stacked device structure 400, dummy source/drain 330 is not confined to source/drain trench 220, and dummy source/drain 330 is formed inside and outside of source/drain trench 220.

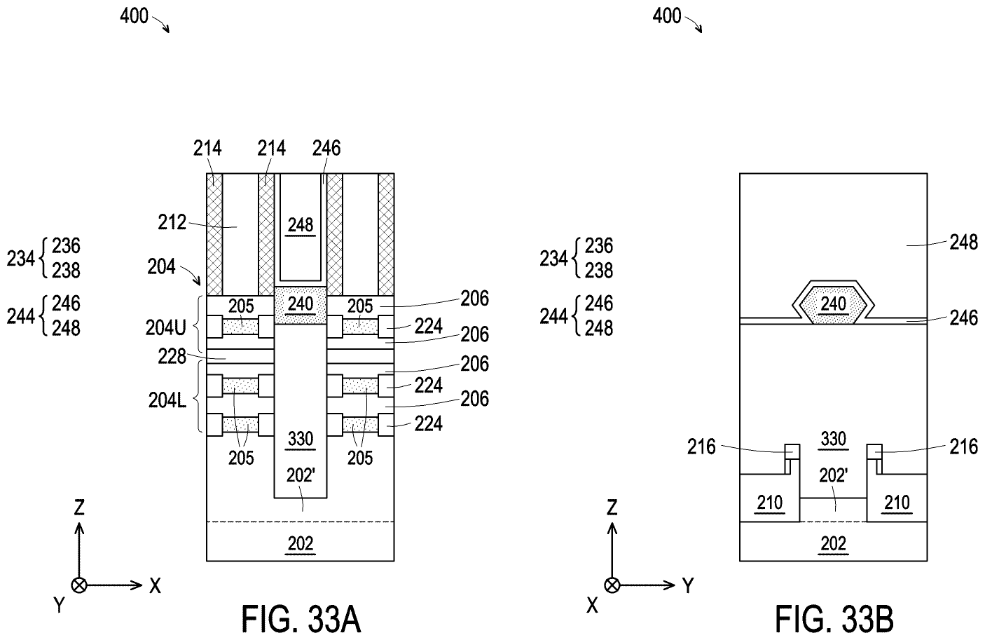

Referring to FIG. 2, FIG. 33A, and FIG. 33B, upper source/drain 240 is formed over dummy source/drain 330 at block 125 of method 100, such as described above with reference to FIG. 21A and FIG. 21B. In stacked device structure 400, since dummy source/drain 330 will function as a source/drain isolation structure, processing associated with block 120 of method 100, such as described above with reference to FIG. 20A and FIG. 20B, is omitted from source/drain fabrication, and upper source/drain 240 is formed directly on dummy source/drain 330 in stacked device structure 400. In other words, dummy source/drain 330 may replace dielectric layer 234 between upper source/drain 240 and lower source/drain 290, and processing associated with forming dielectric layer 234 (e.g., CESL 236 and ILD layer 238) may be omitted when forming source/drains of stacked device structure 400, which may reduce time and/or complexity of source/drain formation. Processing may further include forming dielectric layer 244 over upper source/drain 240, such as depicted. In FIG. 33B, since dielectric layer 234 is not formed in stacked device structure 400, dummy source/drain 330 is not separated from upper source/drain 240 by dielectric layer 234, and dielectric layer 234 is not between dummy source/drain 330 and dielectric layer 244. Dummy source/drain 330 may thus physically, directly contact upper source/drain 240 and/or dielectric layer 244 (e.g., CESL 246 thereof).

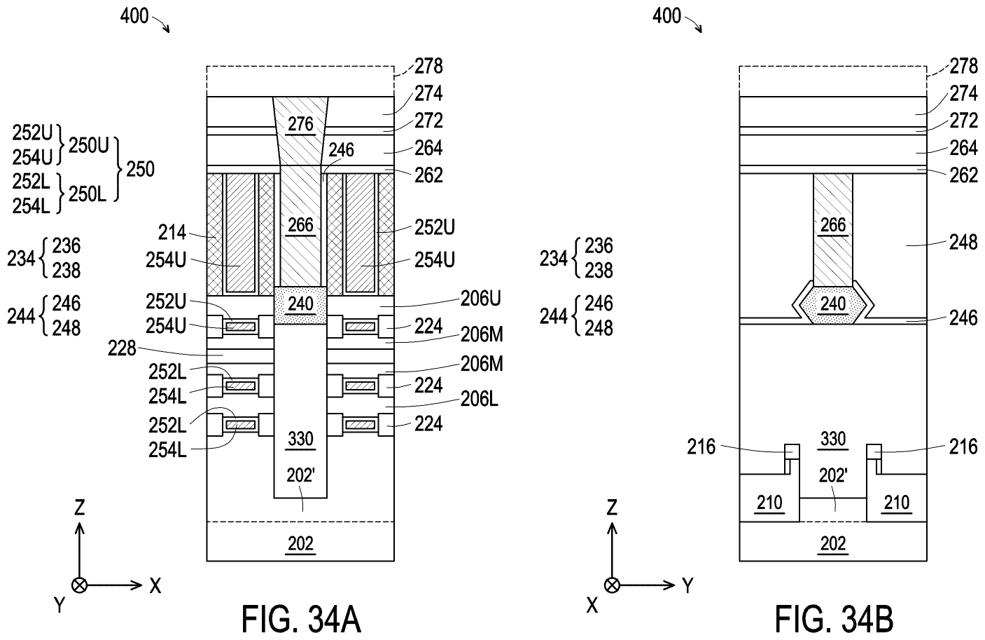

Referring to FIG. 34A and FIG. 34B, processing may further include performing a gate replacement process (e.g., replacing dummy gates 212 (and semiconductor layers 205) with gate stacks 250), performing a channel release process (e.g., providing semiconductor layers 206U, semiconductor layers 206M, and semiconductor layers 206L), forming an upper source/drain interconnect to upper source/drain 240 (e.g., source/drain contact 266 and source/drain via 276, which may be disposed in dielectric layer 244, CESL 262, ILD layer 264, CESL 272, and ILD layer 274), and performing frontside BEOL processing (e.g., to form F-MLI structure 278), such as described above with reference to FIG. 22A and FIG. 22B.

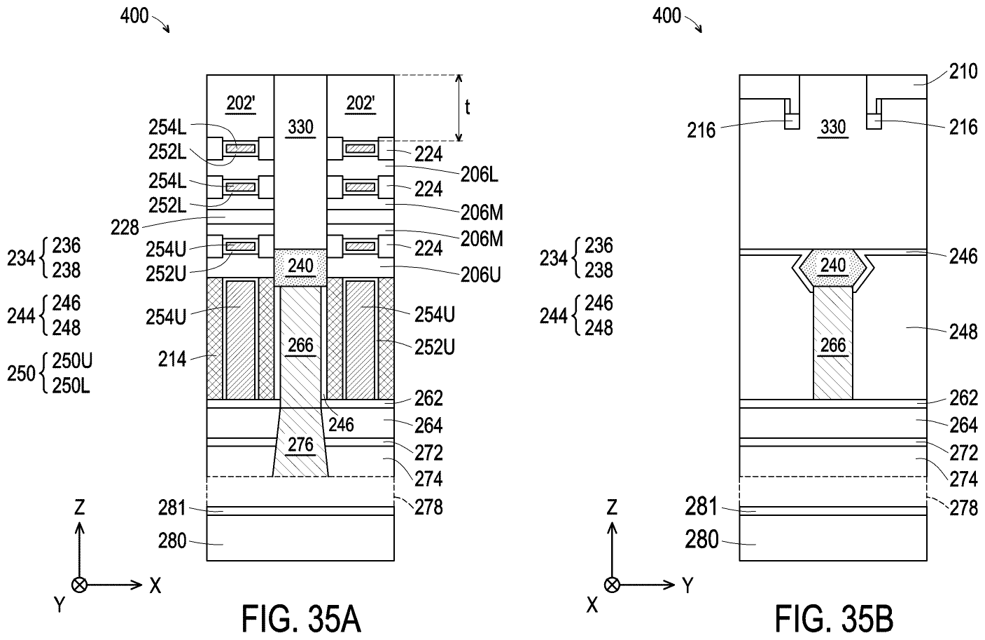

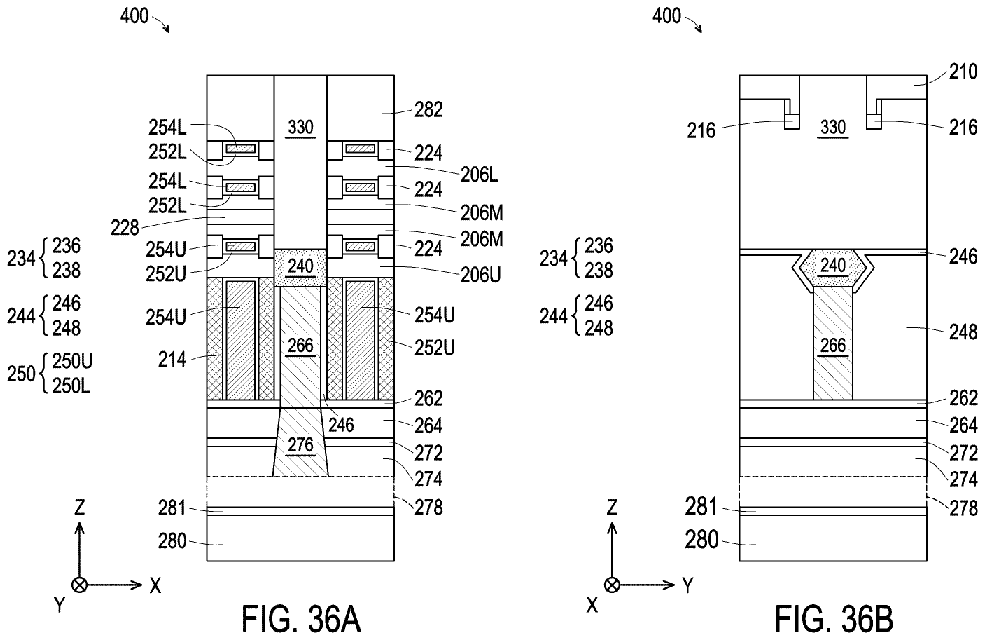

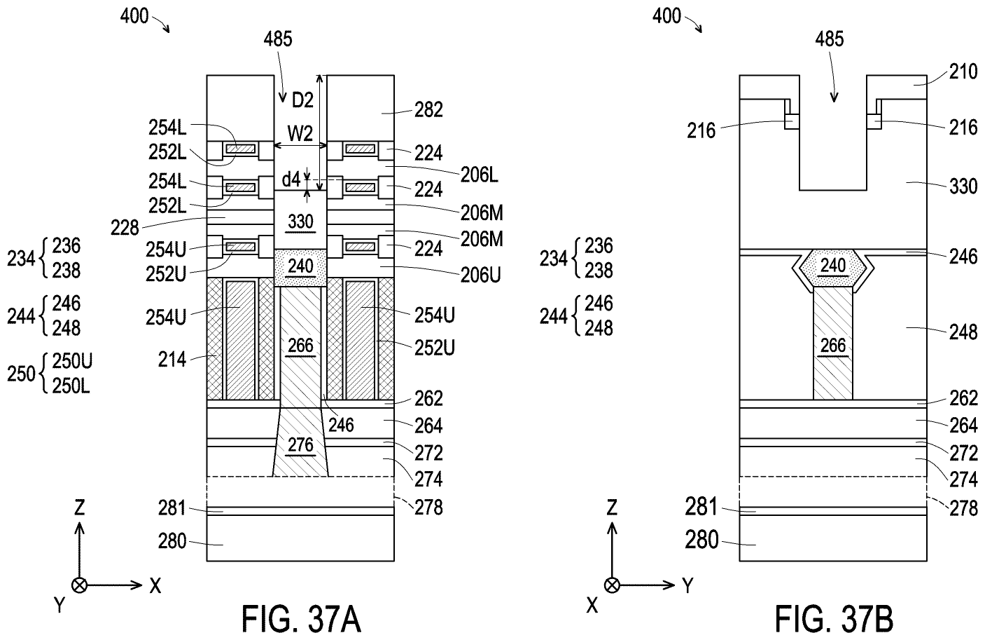

Referring to FIG. 2, FIG. 35A, and FIG. 35B, a backside of dummy source/drain 330 is exposed at block 130 of method 100, such as described above with reference to FIG. 23A and FIG. 23B. Referring to FIG. 36A and FIG. 36B, processing may further include performing a de-mesa process to replace mesas 202′ with backside insulation layer 282, such as described above with reference to FIG. 24A and FIG. 24B. Referring to FIG. 2, FIG. 37A, and FIG. 37B, dummy source/drain 330 is removed to form a backside source/drain trench, such as a source/drain trench 485, at block 135 of method 100, such as described with reference to FIG. 25A and FIG. 25B. In the depicted embodiment, where dummy source/drain 330 provides the source/drain isolation structure, dummy source/drain 330 is partially removed in the source/drain region to form source/drain trench 485, instead of completely removed in the source/drain region to form source/drain trench 385 (see, e.g., stacked device structure 300 in FIG. 25A and FIG. 25B), and a portion of dummy source/drain 330 remains in the source/drain region of stacked device structure 400. In stacked device structure 400, dummy source/drain 330 is etched back/recessed below topmost active layers (e.g., channel layers) of lower transistors to ensure that source/drain trench 485 exposes sidewalls of semiconductor layers 206L (i.e., channel layers of the lower transistors). For example, dummy source/drain 330 may be recessed below semiconductor layers 206L, but not semiconductor layers 206M, of lower transistors, such that dummy source/drain 330 remains adjacent to sidewalls of semiconductor layers 206M. A distance d4 may be between a topmost active layer (e.g., a channel layer) of lower transistors and a top of dummy source/drain 330. In the depicted embodiment, dummy source/drain 330 is above semiconductor layers 206L, extends below semiconductor layers 206M, and extends below a top of lower gate stack 250U. In some embodiments, distance d4 is zero.

In FIG. 37A, source/drain trench 485 has a bottom formed by dummy source/drain 330 and sidewalls formed by backside insulation layer 282, inner spacers 224, and semiconductor layers 206L. In FIG. 37B, in contrast to source/drain trench 385, source/drain trench 485 has a bottom formed by dummy source/drain 330 and sidewalls formed by substrate isolation structure 210, fin spacers 216, and dummy source/drain 330. Source/drain trench 485 may be formed by applying an etching process to the backside of stacked device structure 400. The etching process may selectively remove dummy source/drain 330 with respect to backside insulation layer 282, inner spacers 224, semiconductor layers 206L, or combinations thereof. For example, the etching process etches dummy source/drain 330 with no (or negligible) etching of backside insulation layer 282, inner spacers 224, and semiconductor layers 206L. Parameters of the etching process may be tuned to ensure dummy source/drain 330 has a target thickness, which may provide sufficient electrical isolation between upper source/drain 240 and lower source/drain 290, and that source/drain trench 485 extends sufficiently beyond topmost active layers (e.g., channel layers) of lower transistors. Because dummy source/drain 330 may be selectively removed with respect to backside insulation layer 282, dummy source/drain 330 may be removed without an etch mask and/or without performing a lithography process. Further, because dummy source/drain 330 may be selectively removed with respect to backside insulation layer 282, inner spacers 224, and semiconductor layers 206L, source/drain trench 485 (i.e., a lower source/drain trench) is aligned with the source/drain region of stacked device structure 400 and/or upper source/drain 240 without performing a lithography process (i.e., source/drain trench 485 is self-aligned), thereby reducing time and/or complexity of source/drain fabrication. The etching process is a dry etch, a wet etch, other suitable etch, or combinations thereof.

Source/drain trench 485 has width W2 and depth D2, and source/drain trench 485 has aspect ratio AR_{L}, which is less than the aspect ratio of openings between dummy gates 212 (e.g., a ratio of depth D1 to width W1) after forming source/drain trench 220 (frontside source/drain trench). In the depicted embodiment, in FIG. 37B, source/drain trench 485 has substantially vertical sidewalls. In such embodiments, the etching process may be an anisotropic etch that is configured to remove material in substantially one direction, such as a vertical direction (e.g., z-direction) with minimal (to no) removal of material in a horizonal direction (e.g., x-direction and/or y-direction). In some embodiments, the etching process may remove material (e.g., portions of dummy source/drain 330) along the vertical direction and the horizontal direction (i.e., the etching process may laterally etch dummy source/drain 330). In such embodiments, source/drain trench 485 may extend laterally over/under fin spacers 216 and/or substrate isolation structure 210, and source/drain trench 485 may have tapered sidewalls. For example, a width of source/drain trench 485 may decrease from top to bottom. The present disclosure contemplates various profiles of source/drain trench 485 depending on the etching process.

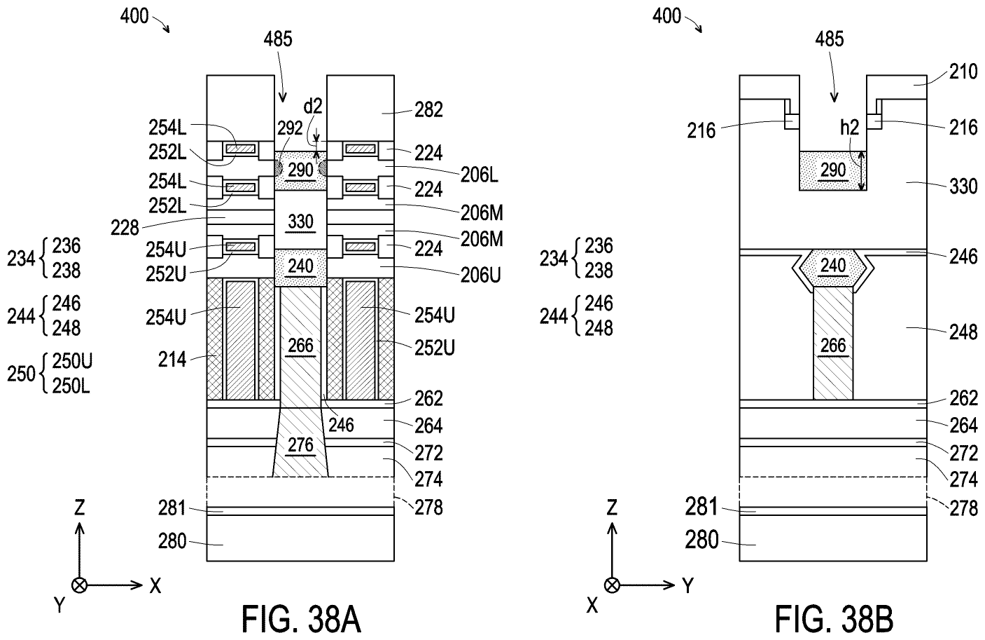

Referring to FIG. 2, FIG. 38A, and FIG. 38B, a lower source/drain, such as lower source/drain 290, is formed in the backside source/drain trench, such as in source/drain trench 485, at block 140 of method 100, such as described above with reference to FIG. 26A and FIG. 26B. Lower source/drain 290 is formed over upper source/drain 240, lower source/drain 290 partially fills source/drain trench 485, and lower source/drain 290 is disposed between and adjacent to semiconductor layers 206L. In the depicted embodiment, lower source/drain 290 is formed over dummy source/drain 290 (i.e., the source/drain isolation structure in stacked device structure 400), and lower source/drain 290 may also have height h2, which is less than depth D2, in source/drain trench 485. Further, since lower source/drain 290 is formed in source/drain trench 485 and after removal of substrate 202, distance d2 may be between the bottom of lower source/drain 290 and the bottoms of gate stacks 250 (i.e., lower source/drain 290 does not extend beyond the bottoms of gate stacks 250), such as described above.

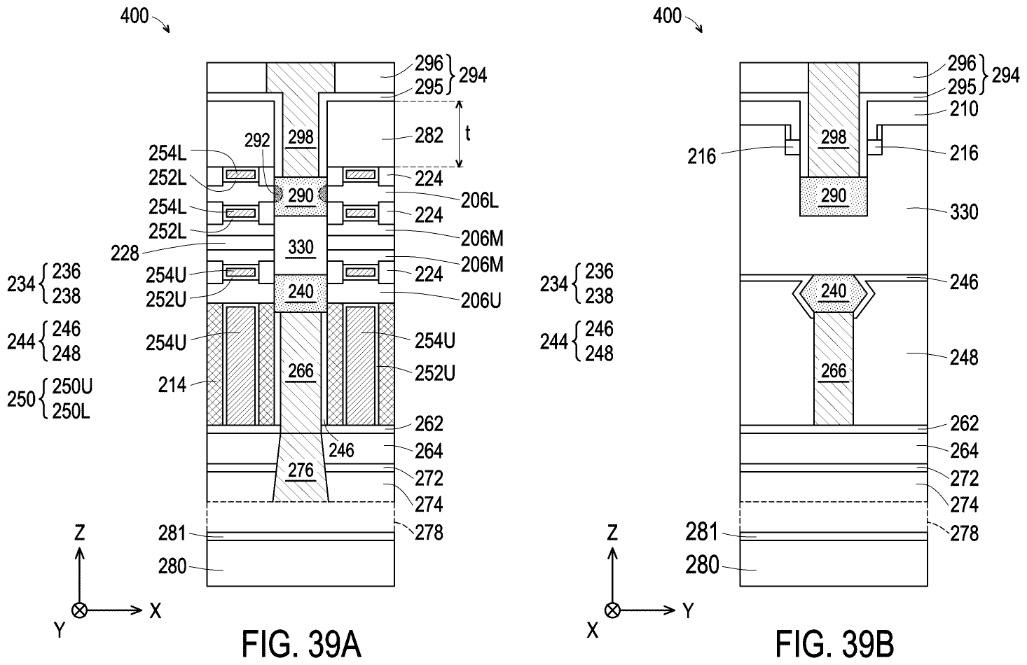

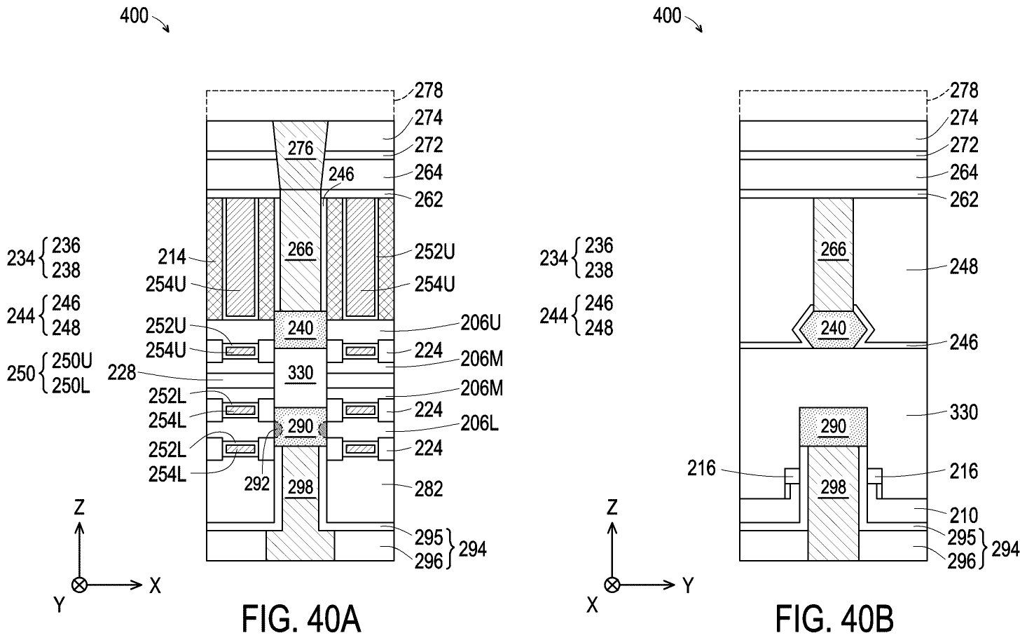

Referring to FIG. 39A and FIG. 39B, processing may further include forming a lower source/drain interconnect, such as source/drain contact 298, to lower source/drain 290, such as described above with reference to FIG. 27A and FIG. 27B. Source/drain contact 298 may be formed in backside insulation layer 282 and/or other insulation layers (e.g., dielectric layer 294, which may include CESL 295 and ILD layer 296). Processing may further include backside BEOL processing to form a B-MLI structure over dielectric layer 294. Referring to FIG. 40A and FIG. 40B, processing may further include flipping over stacked device structure 400, such that F-MLI structure 278 forms a top/frontside thereof and dielectric layer 294 and source/drain contact 298 form a bottom/backside thereof, and removing carrier substrate 280 and/or bonding layer 281, such as described above with reference to FIG. 28A and FIG. 28B.

In some embodiments, transistor 20U, transistor 20L, upper transistors of the stacked device structures described herein, lower transistors of the stacked device structures described herein, or combinations thereof are fabricated as FinFETs. In such embodiments, the gate (e.g., gate stack 90U and/or gate stack 90L) partially surrounds and/or wraps its respective channel(s). For example, the channel is a semiconductor fin, which may extend from a substrate, the gate stack is on a top of the semiconductor fin in the X-Z plane, and the gate stack wraps the semiconductor fin in the Y-Z plane (i.e., the gate stack is disposed on a top and sidewalls of the semiconductor fin). In such embodiments, a gate dielectric and a gate electrode of the gate stack are formed over a top and sidewalls of the semiconductor fin or semiconductor fins.

In some embodiments, transistor 20U, transistor 20L, upper transistors of the stacked device structures described herein, lower transistors of the stacked device structures described herein, or combinations thereof are fabricated as planar transistors. In such embodiments, the gate stack (e.g., gate stack 90U and/or gate stack 90L) is disposed on one side of the channel (e.g., a top surface). For example, the channel is a portion of a semiconductor layer, and the gate stack is disposed on a top surface of semiconductor layer in the X-Z plane and the Y-Z plane. In such embodiments, a gate dielectric and a gate electrode of the gate stack are formed over a top of a channel region of the semiconductor layer.

Devices and/or structures described herein, such as stacked device structure 10, device 12U, device 12L, transistor 20L, transistor 20U, etc. may be included in a microprocessor, a memory, other IC device, or combinations thereof. In some embodiments, devices and/or structures described herein, such as stacked device structure 10, device 12U, device 12L, transistor 20L, transistor 20U, etc. are a portion of an IC chip, a system on chip (SoC), or portion thereof, that includes various passive and active electronic devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other devices, or combinations thereof.

The present disclosure provides for many different embodiments. The source/drain stacks disclosed herein may be implemented in a variety of stacked device types. For example, the source/drain stacks described herein are suitable for stacked planar field-effect transistors (FETs), stacked multigate transistors, such as stacked FinFETs, stacked GAA transistors, stacked omega-gate (Ω-gate) devices, stacked pi-gate (Π-gate) devices, stacked fork-sheet gate devices, or combinations thereof, as well as stacked strained-semiconductor devices, stacked silicon-on-insulator (SOI) devices, stacked partially-depleted SOI devices, stacked fully-depleted SOI devices, other stacked devices, or combinations thereof.

An exemplary method includes forming a frontside source/drain trench, forming a dummy source/drain in the frontside source/drain trench, forming an upper source/drain in the frontside source/drain trench over the dummy source/drain, exposing a backside of the dummy source/drain, removing the dummy source/drain to form a backside source/drain trench, and forming a lower source/drain in the backside source/drain trench. In some embodiments, the frontside source/drain trench has a first aspect ratio, the backside source/drain trench has a second aspect ratio, and the first aspect ratio is greater than the second aspect ratio.

In some embodiments, the method further includes forming a source/drain isolation structure in the frontside source/drain trench before forming the upper source/drain. The source/drain isolation structure is disposed over the dummy source/drain. In some embodiments, forming the source/drain isolation structure includes forming a contact etch stop layer and forming an interlayer dielectric layer. In some embodiments, the method further includes partially removing the dummy source/drain to form the backside source/drain trench, and the lower source/drain is formed over a remaining portion of the dummy source/drain. The remaining portion of the dummy source/drain provides a source/drain isolation structure.

In some embodiments, the method further includes replacing a semiconductor mesa with a backside insulation layer after exposing the backside of the dummy source/drain and before removing the dummy source/drain. In some embodiments, removing the dummy source/drain to form the backside source/drain trench includes performing an etching process without an etch mask. In some embodiments, forming the dummy source/drain in the frontside source/drain trench includes depositing a dummy source/drain material in the frontside source/drain trench and etching back the dummy source/drain material. In some embodiments, forming the dummy source/drain in the frontside source/drain trench includes depositing a dummy source/drain material inside and outside the frontside source/drain trench.

Another exemplary method includes forming a first source/drain trench in a source/drain region adjacent to an upper semiconductor layer and a lower semiconductor layer. The upper semiconductor layer is disposed over the lower semiconductor layer, the lower semiconductor layer is disposed over a substrate, and the first source/drain trench extends into the substrate. The method further includes forming a dummy source/drain in the first source/drain trench, forming an upper source/drain in the first source/drain trench over the dummy source/drain, removing the dummy source/drain to form a second source/drain trench in the source/drain region after forming the upper source/drain, and forming a lower source/drain in the second source/drain trench. The dummy source/drain is disposed in the substrate, the dummy source/drain is adjacent to the lower semiconductor layer, and the dummy source/drain is below the upper semiconductor layer. The upper source/drain is adjacent to the upper semiconductor layer. The second source/drain trench is disposed adjacent to the lower semiconductor layer. The lower source/drain is adjacent to the lower semiconductor layer.

In some embodiments, forming the dummy source/drain in the first source/drain trench includes epitaxially growing a semiconductor material. In some embodiments, forming the dummy source/drain in the first source/drain trench includes depositing a dielectric material. In some embodiments, removing the dummy source/drain to form the second source/drain trench in the source/drain region includes completely removing the dummy source/drain from the source/drain region. In some embodiments, removing the dummy source/drain to form the second source/drain trench in the source/drain region includes partially removing the dummy source/drain from the source/drain region.

In some embodiments, the method further includes replacing the substrate with a backside dielectric layer before removing the dummy source/drain to form the second source/drain trench and selectively removing the dummy source/drain relative to the backside dielectric layer. In some embodiments, the method further includes further comprising forming a dielectric layer over the dummy source/drain in the first source/drain trench before forming the upper source/drain, wherein the upper source/drain is formed over the dielectric layer.

An exemplary stacked semiconductor structure includes a gate stack and a source/drain stack. The gate stack includes a lower gate and an upper gate disposed over the lower gate. The lower gate is disposed on and engages a lower semiconductor layer, the upper gate is disposed on and engages an upper semiconductor layer, and the upper semiconductor layer is disposed over the lower semiconductor layer. The source/drain stack includes a lower epitaxial source/drain, a source/drain isolation layer disposed over the lower epitaxial source/drain, and an upper epitaxial source/drain disposed over the source/drain isolation layer. The lower epitaxial source/drain is adjacent to the lower semiconductor layer and the lower gate, and the upper epitaxial source/drain is adjacent to the upper semiconductor layer and the upper gate. The lower epitaxial source/drain is disposed in the source/drain isolation layer, and the upper epitaxial source/drain is disposed in an insulation layer. The source/drain isolation layer is formed of a first material, the insulation layer is formed of a second material, and the first material is different than the second material. In some embodiments, the first material has a first dielectric constant that is less than a second dielectric constant of the second material. In some embodiments, the first material includes boron and nitrogen, and the second material includes silicon and oxygen. In some embodiments, a bottom of the lower epitaxial source/drain is above a bottom of the lower gate. In some embodiments, the source/drain isolation layer is free of a contact etch stop layer. In some embodiments, the source/drain isolation layer is a single layer. In some embodiments, the source/drain isolation layer includes boron.

In some embodiments, the upper gate is disposed on and engages at least two sides of the upper semiconductor layer, and the lower gate is disposed on and engages at least two sides of the lower semiconductor layer. In some embodiments, the upper semiconductor layer, the lower semiconductor layer, or both are nanowires, nanosheets, nanobars, or other nanostructure (i.e., suspended channel layers). In such embodiments, the lower gate may wrap around a respective nanostructure (e.g., the lower gate may be disposed on a top, a bottom, and sidewalls of a suspended semiconductor layer) and/or the upper gate may wrap around a respective nanostructure (e.g., the upper gate may be disposed on a top, a bottom, and sidewalls of a suspended semiconductor layer). In some embodiments, the lower gate may partially wrap around a respective nanostructure (e.g., the lower gate may be disposed on a top, a bottom, and one sidewall of a suspended semiconductor layer) and/or the upper gate may partially wrap around a respective nanostructure (e.g., the upper gate may be disposed on a top, a bottom, and one sidewall of a suspended semiconductor layer). In such embodiments, the stacked semiconductor structure may include upper transistors and/or lower transistors configured as fork-sheet transistors. In some embodiments, the upper semiconductor layer, the lower semiconductor layer, or both are semiconductor fins. In such embodiments, the lower gate may wrap a respective semiconductor fin (e.g., the lower gate may be disposed on a top and sidewalls of the semiconductor fin) and/or the upper gate may wrap a respective semiconductor fin (e.g., the upper gate may be disposed on a top and sidewalls of the semiconductor fin).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first source/drain trench having a first aspect ratio;
filling a first portion of the first source/drain trench with a sacrificial source/drain, wherein the sacrificial source/drain is formed of an insulation material and the first portion of the first source/drain trench corresponds with a first device;
filling a second portion of the first source/drain trench with a first source/drain, wherein the first source/drain is formed of a first semiconductor material and the second portion of the first source/drain trench corresponds with a second device;
after filling the second portion of the first source/drain trench with the first source/drain, at least partially removing the sacrificial source/drain to form a second source/drain trench having a second aspect ratio less than the first aspect ratio; and
filling a portion of the second source/drain trench with a second source/drain, wherein the second source/drain is formed of a second semiconductor material and the portion of the second source/drain trench corresponds with the first device.

2. The method of claim 1, wherein filling the first portion of the first source/drain trench with the sacrificial source/drain includes:
depositing a dielectric material in the first source/drain trench; and
etching back the dielectric material, such that the dielectric material is removed from the second portion of the first source/drain trench that corresponds with the second device.

3. The method of claim 2, wherein:
the depositing the dielectric material includes performing a blanket deposition process, such that the dielectric material is deposited inside and outside the first source/drain trench; and
a portion of the dielectric material remains outside the first source/drain trench after the etching back of the dielectric material.

4. The method of claim 2, wherein:
the depositing the dielectric material includes performing a spin-on deposition process, such that the dielectric material is deposited inside and outside the first source/drain trench; and
a portion of the dielectric material remains outside the first source/drain trench after the etching back of the dielectric material.

5. The method of claim 1, further comprising:
before filling the second portion of the first source/drain trench with the first source/drain, filling a third portion of the first source/drain trench with a source/drain isolation structure, wherein the third portion of the first source/drain trench is disposed between the first portion of the first source/drain trench and the second portion of the first source/drain trench and the third portion of the first source/drain trench corresponds with a device isolation region between the first device and the second device; and
completely removing the sacrificial source/drain to form the second source/drain trench.

6. The method of claim 5, wherein the filling the third portion of the first source/drain trench with the source/drain isolation structure includes:
forming a contact etch stop layer over the sacrificial source/drain, wherein the contact etch stop layer is formed inside and outside the first source/drain trench; and
forming an interlayer dielectric layer over the contact etch stop layer, wherein the interlayer dielectric layer is formed inside and outside the first source/drain trench.

7. The method of claim 1, further comprising:
filling a third portion of the first source/drain trench with the sacrificial source/drain, wherein the third portion of the first source/drain trench is disposed between the first portion of the first source/drain trench and the second portion of the first source/drain trench and the third portion of the first source/drain trench corresponds with a device isolation region between the first device and the second device; and
partially removing the sacrificial source/drain to form the second source/drain trench, wherein a remainder of the sacrificial source/drain provides a source/drain isolation structure between the first source/drain and the second source/drain.

8. The method of claim 1, wherein the filling the portion of the second source/drain trench with the second source/drain includes epitaxially growing the second semiconductor material and implementing an epitaxial growth temperature that is less than about 400° C.

9. The method of claim 1, wherein:
the first aspect ratio is at least 10;
the second aspect ratio is at least 1; and
the second aspect ratio is less than 10.

10. The method of claim 9, wherein:
a first width of the first source/drain trench is less than about 20 nm; and
a second width of the second source/drain trench is less than about 20 nm.

11. A method comprising:
forming a source/drain trench that extends through an upper multilayer stack, a lower multilayer stack, an intermediate stack between the upper multilayer stack and the lower multilayer stack, and into a semiconductor substrate;
depositing a dielectric material in the source/drain trench and etching back the dielectric material to form a dielectric layer in a portion of the source/drain trench disposed in the lower multilayer stack and in the semiconductor substrate;
forming a first type source/drain over the dielectric layer in a portion of the source/drain trench disposed in the upper multilayer stack;
after removing a portion of the semiconductor substrate to expose the dielectric layer, replacing at least a portion of the dielectric layer with a second type source/drain; and
before replacing at least the portion of the dielectric layer with the second type source/drain, replacing a portion of the upper multilayer stack with a first gate stack and a portion of the lower multilayer stack with a second gate stack.

12. The method of claim 11, wherein the source/drain trench is a first source/drain trench, the method further comprising:
after removing the portion of the semiconductor substrate to expose the dielectric layer, replacing the semiconductor substrate with an insulation structure; and
wherein the replacing at least the portion of the dielectric layer with the second type source/drain includes:
selectively removing the dielectric layer with respect to the insulation structure, semiconductor layers of the lower multilayer stack, and inner spacers of the lower multilayer stack to form a second source/drain trench, and
epitaxially growing a semiconductor material in the second source/drain trench using a temperature less than about 400° C.

13. The method of claim 12, wherein the semiconductor material partially fills the second source/drain trench, the method further comprising filling a remainder of the second source/drain trench with a contact etch stop layer and an interlayer dielectric layer.

14. The method of claim 12, wherein the selectively removing the dielectric layer to form the second source/drain trench completely removes the dielectric layer from a source/drain region to expose a source/drain isolation structure, wherein the source/drain isolation structure remains between the first type source/drain and the second type source/drain.

15. The method of claim 12, wherein the selectively removing the dielectric layer to form the second source/drain trench partially removes the dielectric layer from a source/drain region, wherein a remainder of the dielectric layer in the source/drain region remains disposed between the first type source/drain and the second type source/drain.

16. The method of claim 11, wherein the dielectric material is formed of a silicon-comprising material that includes oxygen, carbon, nitrogen, or combinations thereof.

17. The method of claim 11, wherein the dielectric material is formed of a boron-comprising material that includes oxygen, carbon, nitrogen, or combinations thereof.

18. A device structure comprising:
a source/drain stack that includes a first source/drain, a second source/drain disposed over the first source/drain, and a source/drain isolation structure disposed between the second source/drain and the first source/drain, wherein the first source/drain is formed of a first semiconductor material, the second source/drain is formed of a second semiconductor material, and the second semiconductor material is different from the first semiconductor material;
a contact etch stop layer and an interlayer dielectric layer disposed over the second source/drain, wherein the contact etch stop layer is disposed between sidewalls of the second source/drain and the interlayer dielectric layer; and
a dummy source/drain layer disposed between the contact etch stop layer and a substrate isolation structure, wherein the dummy source/drain layer is formed of an insulation material and the dummy source/drain layer is disposed along sidewalls of the first source/drain.

19. The device structure of claim 18, wherein the source/drain isolation structure is formed from the dummy source/drain layer.

20. The device structure of claim 18, wherein the contact etch stop layer is a first contact etch stop layer, the interlayer dielectric layer is a first interlayer dielectric layer, and the source/drain isolation structure is formed from a second contact etch stop layer and a second interlayer dielectric layer, wherein the second contact etch stop layer is disposed between the dummy source/drain layer and the second interlayer dielectric layer.
